(19) United States
(12) Patent Application Publication
(10) Pub. No.: US 2025/0374702 A1
(43) Pub. Date: Dec. 4, 2025

(54) IMAGING ELEMENT AND ELECTRONIC DEVICE

(71) Applicant: SONY SEMICONDUCTOR SOLUTIONS CORPORATION, Kanagawa (JP)

(72) Inventors: Koki TACHIYAMA, Tokyo (JP); Chihiro TOMITA, Kanagawa (JP)

(73) Assignee: SONY SEMICONDUCTOR SOLUTIONS CORPORATION, Kanagawa (JP)

(21) Appl. No.: 18/875,533

(22) PCT Filed: Jun. 15, 2023
(86) PCT No.: PCT/JP2023/022291

§ 371 Date: Dec. 16, 2024

(30) Foreign Application Priority Data
Jun. 24, 2022 (JP) 2022-102261

(51) Int. Cl. H10F 39/00

(52) U.S. Cl. CPC H10F 39/812; H10F 39/802; H10F 39/807; H10F 39/811

(57) ABSTRACT

An imaging element is miniaturized. The imaging element includes pixels, well region electrodes, and signal generation sections. A pixel includes: a photoelectric conversion section that performs photoelectric conversion of incident light, the photoelectric conversion section formed in a semiconductor substrate; a charge holding section that holds a charge generated by the photoelectric conversion; and a charge transfer section that transfers the charge to the charge holding section. A well region electrode is disposed by being embedded in the semiconductor substrate and connected to a well region of the semiconductor substrate. A signal generation section generates a pixel signal that is a signal corresponding to the charge held in the charge holding section.

### FIELD

The present disclosure relates to an imaging element and an electronic device.

### BACKGROUND

Imaging elements of a complementary metal oxide semiconductor (CMOS) type, in which a plurality of pixels is arranged, are used. Arranged in a pixel are a photoelectric conversion section including a photodiode that performs photoelectric conversion of incident light, a charge holding section that holds a charge generated by the photoelectric conversion, and a transfer transistor that transfers the charge from the photoelectric conversion section to the charge holding section. A signal corresponding to the charge held in the charge holding section is generated and output as an image signal. Among such imaging elements, an imaging element configured by stacking a semiconductor substrate (sensor substrate), in which pixels are arranged, and a semiconductor substrate (transistor substrate), in which a circuit that generates an image signal is disposed, are proposed (see, for example, Patent Literature 1.).

In the imaging element described above, in order to supply a reference potential from the transistor substrate to the sensor substrate, a via plug for transmitting the reference potential to the transistor substrate and the sensor substrate is disposed. The via plug is connected to a well region of the sensor substrate and transmits the reference potential.

### CITATION LIST

### Patent Literature

Patent Literature 1: WO 2020/262643 A

### SUMMARY

### Technical Problem

However, in the technology in the related art described above, a semiconductor region for connecting the via plug for transmitting the reference potential to the well region is disposed for each pixel, and thus there is an issue that miniaturization is difficult.

Therefore, the present disclosure proposes an imaging element and an electronic device that are easily miniaturized.

### Solution to Problem

An imaging element according to the present disclosure includes pixels, well region electrode and signal generation section. A pixel includes: a photoelectric conversion section that performs photoelectric conversion of incident light, the photoelectric conversion section formed in a semiconductor substrate; a charge holding section that holds a charge generated by the photoelectric conversion; and a charge transfer section that transfers the charge to the charge holding section. A well region electrode is disposed by being embedded in the semiconductor substrate, the well region electrode connected to a well region of the semiconductor substrate. A signal generation section generates a pixel signal that is a pixel signal corresponding to the charge held in the charge holding section

Furthermore, An electronic device according to the present disclosure includes pixels, well region electrodes, signal generation section and a processing circuit. a pixel includes: a photoelectric conversion section that performs photoelectric conversion of incident light, the photoelectric conversion section formed in a semiconductor substrate; a charge holding section that holds a charge generated by the photoelectric conversion; and a charge transfer section that transfers the charge to the charge holding section. A well region electrode is disposed by being embedded in the semiconductor substrate, the well region electrode connected to a well region of the semiconductor substrate. A signal generation section generates a pixel signal that is a signal corresponding to the charge held in the charge holding section. The processing circuit processes the pixel signal.

### BRIEF DESCRIPTION OF DRAWINGS

FIG. 1 is a diagram illustrating a configuration example of an imaging element according to an embodiment of the present disclosure.

FIG. 2 is a circuit diagram illustrating a configuration example of a pixel block according to a first embodiment of the present disclosure.

FIG. 3 is a diagram illustrating a structure example of the pixel block according to the first embodiment of the present disclosure.

FIG. 4 is a diagram illustrating a structure example of the pixel block according to the first embodiment of the present disclosure.

FIG. 5 is a diagram illustrating a structure example of the pixel block according to the first embodiment of the present disclosure.

FIG. 6A is a diagram illustrating an example of the manufacturing method of an imaging element according to the first embodiment of the disclosure.

FIG. 6B is a diagram illustrating an example of the manufacturing method of the imaging element according to the first embodiment of the disclosure.

FIG. 6C is a diagram illustrating an example of the manufacturing method of the imaging element according to the first embodiment of the disclosure.

FIG. 6D is a diagram illustrating an example of the manufacturing method of the imaging element according to the first embodiment of the disclosure.

FIG. 6E is a diagram illustrating an example of the manufacturing method of the imaging element according to the first embodiment of the disclosure.

FIG. 6F is a diagram illustrating an example of the manufacturing method of the imaging element according to the first embodiment of the disclosure.

FIG. 6G is a diagram illustrating an example of the manufacturing method of the imaging element according to the first embodiment of the disclosure.

FIG. 6H is a diagram illustrating an example of the manufacturing method of the imaging element according to the first embodiment of the disclosure.

FIG. 6I is a diagram illustrating an example of the manufacturing method of the imaging element according to the first embodiment of the disclosure.

FIG. 6J is a diagram illustrating an example of the manufacturing method of the imaging element according to the first embodiment of the disclosure.

FIG. 6K is a diagram illustrating an example of the manufacturing method of the imaging element according to the first embodiment of the disclosure.

FIG. 6L is a diagram illustrating an example of the manufacturing method of the imaging element according to the first embodiment of the disclosure.

FIG. 7 is a diagram illustrating a structure example of a pixel block according to a first modification of the first embodiment of the disclosure.

FIG. 8 is a diagram illustrating a structure example of a pixel block according to a first modification of the first embodiment of the disclosure.

FIG. 9 is a diagram illustrating a structure example of the pixel block according to a second modification of the first embodiment of the present disclosure.

FIG. 10 is a diagram illustrating a structure example of a pixel block according to a third modification of the first embodiment of the disclosure.

FIG. 11 is a diagram illustrating a structure example of a pixel block according to a fourth modification of the first embodiment of the disclosure.

FIG. 12 is a diagram illustrating a structure example of the pixel block according to the fourth modification of the first embodiment of the disclosure.

FIG. 13 is a diagram illustrating a structure example of the pixel block according to the fourth modification of the first embodiment of the disclosure.

FIG. 14A is a diagram illustrating a structure example of a pixel block according to a fifth modification of the first embodiment of the disclosure.

FIG. 14B is a diagram illustrating a structure example of a pixel block according to the fifth modification of the first embodiment of the disclosure.

FIG. 15 is a diagram illustrating a structure example of a pixel block according to a sixth modification of the first embodiment of the disclosure.

FIG. 16A is a diagram illustrating a structure example of a pixel block according to a seventh modification of the first embodiment of the disclosure.

FIG. 16B is a diagram illustrating a structure example of a pixel block according to the seventh modification of the first embodiment of the disclosure.

FIG. 17 is a diagram illustrating a structure example of a pixel block according to an eighth modification of the first embodiment of the disclosure.

FIG. 18 is a diagram illustrating a structure example of a pixel block according to a second embodiment of the present disclosure.

FIG. 19A is a diagram illustrating a structure example of the pixel block according to the second embodiment of the disclosure.

FIG. 19B is a diagram illustrating a structure example of the pixel block according to the second embodiment of the disclosure.

FIG. 20 is a diagram illustrating a structure example of the pixel block according to the second embodiment of the present disclosure.

FIG. 21A is a diagram illustrating an example of the manufacturing method of an imaging element according to the second embodiment of the disclosure.

FIG. 21B is a diagram illustrating an example of the manufacturing method of the imaging element according to the second embodiment of the disclosure.

FIG. 21C is a diagram illustrating an example of the manufacturing method of the imaging element according to the second embodiment of the disclosure.

FIG. 21D is a diagram illustrating an example of the manufacturing method of the imaging element according to the second embodiment of the disclosure.

FIG. 21E is a diagram illustrating an example of the manufacturing method of the imaging element according to the second embodiment of the disclosure.

FIG. 21F is a diagram illustrating an example of the manufacturing method of the imaging element according to the second embodiment of the disclosure.

FIG. 21G is a diagram illustrating an example of the manufacturing method of the imaging element according to the second embodiment of the disclosure.

FIG. 21H is a diagram illustrating an example of the manufacturing method of the imaging element according to the second embodiment of the disclosure.

FIG. 21I is a diagram illustrating an example of the manufacturing method of the imaging element according to the second embodiment of the disclosure.

FIG. 21J is a diagram illustrating an example of the manufacturing method of the imaging element according to the second embodiment of the disclosure.

FIG. 21K is a diagram illustrating an example of the manufacturing method of the imaging element according to the second embodiment of the disclosure.

FIG. 21L is a diagram illustrating an example of the manufacturing method of the imaging element according to the second embodiment of the disclosure.

FIG. 21M is a diagram illustrating an example of the manufacturing method of the imaging element according to the second embodiment of the disclosure.

FIG. 22 is a diagram illustrating a structure example of a pixel block according to a first modification of the second embodiment of the disclosure.

FIG. 23 is a diagram illustrating a structure example of a pixel block according to a second modification of the second embodiment of the disclosure.

FIG. 24 is a diagram illustrating a structure example of a pixel block according to a third modification of the second embodiment of the disclosure.

FIG. 25 is a diagram illustrating a structure example of a pixel block according to a fourth modification of the second embodiment of the disclosure.

FIG. 26 is a diagram illustrating a structure example of a pixel block according to a fifth modification of the second embodiment of the disclosure.

FIG. 27A is a diagram illustrating a structure example of a pixel block according to a sixth modification of the second embodiment of the disclosure.

FIG. 27B is a diagram illustrating a structure example of the pixel block according to the sixth modification of the second embodiment of the disclosure.

FIG. 28 is a diagram illustrating a structure example of the pixel block according to the sixth modification of the second embodiment of the disclosure.

FIG. 29 is a diagram illustrating another configuration example of an imaging element.

FIG. 30 is a cross-sectional view illustrating another configuration example of the imaging element.

FIG. 31 is a diagram illustrating an example of a schematic configuration of an imaging system including an imaging device according to one of the embodiments and the modifications thereof.

FIG. 32 is a diagram illustrating an example of an imaging procedure of the imaging system illustrated in FIG. 31.

FIG. 33 is a block diagram depicting an example of schematic configuration of a vehicle control system.

FIG. 34 is a diagram of assistance in explaining an example of installation positions of an outside-vehicle information detecting section and an imaging section.

FIG. 35 is a view depicting an example of a schematic configuration of an endoscopic surgery system.

FIG. 36 is a block diagram depicting an example of a functional configuration of a camera head and a camera control unit (CCU).

### DESCRIPTION OF EMBODIMENTS

Hereinafter, embodiments of the present disclosure will be described in detail on the basis of the drawings. Description will be given in the following order. Note that in each of the following embodiments, the same parts are denoted by the same symbols, and redundant description will be omitted.
1. First Embodiment
2. Modifications of First Embodiment
3. Second Embodiment
4. Modifications of Second Embodiment
5. Other Structure Examples
6. Application Examples
7. Application Example to Mobile Body
8. Application Example to Endoscopic Surgery System

### 1. First Embodiment

### Configuration of Imaging Element

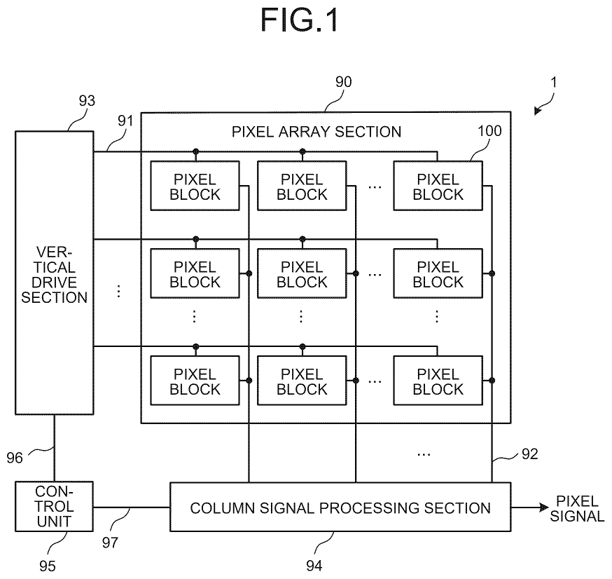

FIG. 1 is a diagram illustrating a configuration example of an imaging element according to an embodiment of the present disclosure. The drawing is a block diagram illustrating a configuration example of an imaging element 1. An electronic device according to an embodiment of the present disclosure will be described by taking the imaging element 1 as an example. The imaging element 1 is a semiconductor element that generates image data of a subject. The imaging element 1 includes a pixel array section 90, a vertical drive section 93, a column signal processing section 94, and a control unit 95.

The pixel array section 90 includes a plurality of pixel blocks 100 arranged therein. In the pixel array section 90, a plurality of pixel blocks 100 is arranged in a shape of a two-dimensional matrix. In this example, a pixel block 100 includes: a plurality of pixels having a photoelectric conversion section that performs photoelectric conversion of incident light; and a charge holding section (charge holding sections 103a to 103d to be described later) that holds a charge generated by the photoelectric conversion. For example, a photodiode can be used for the photoelectric conversion section. Furthermore, a pixel circuit (pixel circuit 120 to be described later) is disposed in each of the pixel blocks 100. The pixel circuit 120 generates a pixel signal on the basis of a charge held in charge holding sections 103a to 103d of the pixel block 100.

A signal line 91 is wired to each of the pixel blocks 100. The pixel block 100 is controlled by a control signal transmitted by the signal line 91. Furthermore, a signal line 92 is wired in the pixel block 100. A pixel signal is output from the pixel block 100 to the signal line 92. Note that a signal line 91 is disposed for each of rows shaping a two-dimensional matrix and is wired in a shared manner to a plurality of pixel blocks 100 arranged in one row. A signal line 92 is disposed in the column direction of the two-dimensional matrix and is wired in a shared manner to a plurality of pixel blocks 100 arranged in one column.

The vertical drive section 93 generates control signals for the pixel blocks 100 described above. The vertical drive section 93 in the drawing generates a control signal for each of the rows of the two-dimensional matrix of the pixel array section 90 and sequentially outputs the control signals via a signal line 91.

The column signal processing section 94 processes a pixel signal generated by a pixel block 100. The column signal processing section 94 in the drawing simultaneously processes pixel signals from a plurality of pixel blocks 100 arranged in one row of the pixel array section 90 transmitted via a signal line 92. As this processing, for example, analog-digital conversion for converting an analog pixel signal generated by a pixel block 100 into a digital pixel signal or correlated double sampling (CDS) for removing an offset error of the pixel signal can be performed. The processed pixel signal is output to a circuit or the like outside the imaging element 1.

The control unit 95 controls the vertical drive section 93 and the column signal processing section 94. The control unit 95 in the drawing outputs control signals via each of signal lines 96 and 97 to control the vertical drive section 93 and the column signal processing section 94. Note that the pixel array section 90 in the drawing is an example of an imaging element. The column signal processing section 94 is an example of the processing circuit. Furthermore, the imaging element 1 in the drawing is an example of the electronic device.

### Configuration of Pixel

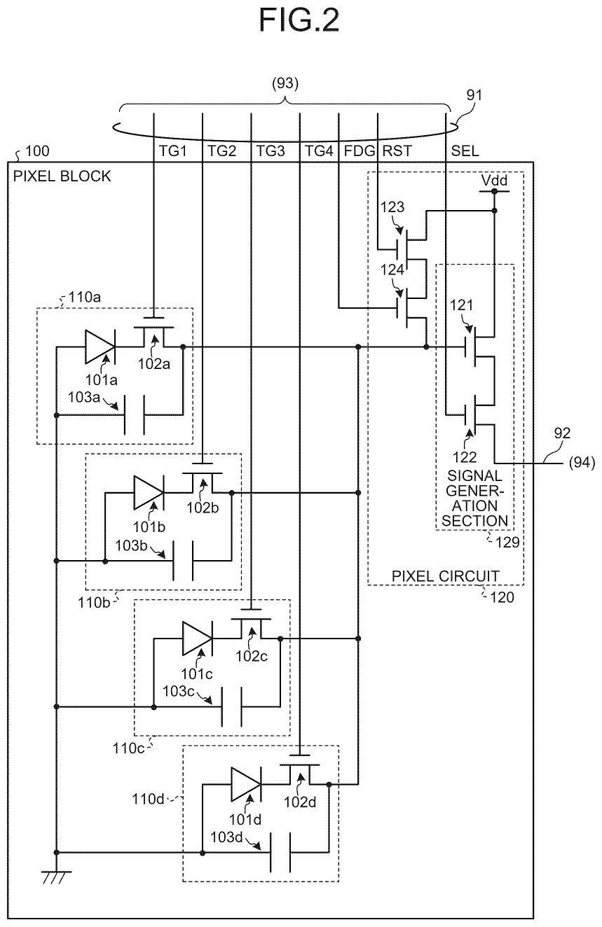

FIG. 2 is a circuit diagram illustrating a configuration example of a pixel block according to a first embodiment of the present disclosure. The drawing is a circuit diagram illustrating a configuration example of a pixel block 100. The pixel block 100 in the drawing includes pixels 110a to 110d and a pixel circuit 120.

The pixel 110a includes a photoelectric conversion section 101a, a charge transfer section 102a, and a charge holding section 103a. The pixel 110b includes a photoelectric conversion section 101b, a charge transfer section 102b, and a charge holding section 103b. The pixel 110c includes a photoelectric conversion section 101c, a charge transfer section 102c, and a charge holding section 103c. The pixel 110d includes a photoelectric conversion section 101d, a charge transfer section 102d, and a charge holding section 103d. A photodiode can be used for the photoelectric conversion sections 101a to 101d. An n-channel MOS transistor can be used for the charge transfer sections 102a to 102d.

The pixel circuit 120 includes a reset transistor 123, a coupling transistor 124, an amplification transistor 121, and a selection transistor 122. An n-channel MOS transistor can be used for the reset transistor 123, the coupling transistor 124, the amplification transistor 121, and the selection transistor 122.

As described above, the signal line 91 and the signal line 92 are wired in the pixel block 100. The signal line 91 in the drawing includes a signal line TG1 to TG4, a signal line FDG, a signal line RST, and a signal line SEL. In addition, a power supply line Vdd is wired in the pixel block 100. The power supply line Vdd supplies power to the pixel block 100.

An anode of the photoelectric conversion section 101a is grounded, and a cathode is connected to a source of the charge transfer section 102a. An anode of the photoelectric conversion section 101b is grounded, and a cathode is connected to a source of the charge transfer section 102b. An anode of the photoelectric conversion section 101c is grounded, and a cathode is connected to a source of the charge transfer section 102c. An anode of the photoelectric conversion section 101d is grounded, and a cathode is connected to a source of the charge transfer section 102d.

Drains of the charge transfer sections 102a to 102d are connected to a source of the coupling transistor 124, a gate of the amplification transistor 121, and first ends of the charge holding sections 103a to 103d. Second ends of the charge holding sections 103a to 103d are grounded. A drain of the coupling transistor 124 is connected to a source of the reset transistor 123. A drain of the reset transistor 123 and a drain of the amplification transistor 121 are connected to the power supply line Vdd. A source of the amplification transistor 121 is connected to a drain of the selection transistor 122, and a source of the selection transistor 122 is connected to the signal line 92.

Gates of the charge transfer sections 102a to 102d are connected to the signal lines TG1 to TG4, respectively. A gate of the coupling transistor 124 is connected to the signal line FDG, a gate of the reset transistor 123 is connected to the signal line RST, and a gate of the selection transistor 122 is connected to the signal line SEL.

The photoelectric conversion sections 101a to 101d perform photoelectric conversion of incident light. The photoelectric conversion sections 101a to 101d can include a photodiode formed on a semiconductor substrate 130 to be described later. The photoelectric conversion sections 101a to 101d perform photoelectric conversion of incident light in an exposure period and hold a charge generated by the photoelectric conversion.

The charge holding sections 103a to 103d hold a charge generated by the photoelectric conversion sections 101a to 101d, respectively. The charge holding sections 103a to 103d can include a floating diffusion (FD) region which is a semiconductor region formed in the semiconductor substrate 130.

The charge transfer sections 102a to 102d transfer a charge. The charge transfer sections 102a to 102d transfer the charge generated by the photoelectric conversion sections 101a to 101d to the charge holding sections 103a to 103d, respectively. The charge transfer section 102a and others transfer a charge by electrically connecting the photoelectric conversion section 101a and others to the charge holding section 103 and others, respectively. Control signals for the charge transfer sections 102a to 102d are transmitted by the signal lines TG1 to TG4, respectively.

The pixel circuit 120 generates a pixel signal on the basis of charges held by the charge holding sections 103a to 103d. As described above, the pixel circuit 120 includes the coupling transistor 124, the reset transistor 123, the amplification transistor 121, and the selection transistor 122.

The coupling transistor 124 couples the capacitance connected to the drain thereof to the charge holding sections 103a to 103d. By this coupling of the capacitance, the holding capacitance of the charge holding section 103a and others can be increased, and the sensitivity of the pixel 110a and others can be switched. A control signal for the coupling transistor 124 is transmitted by the signal line FDG.

The reset transistor 123 resets the charge holding sections 103a to 103d. This reset can be performed by discharging the charges of the charge holding sections 103a to 103d by electrically connecting the charge holding sections 103a to 103d and the power supply line Vdd. At the time of this reset, the above-described coupling transistor 124 is made conductive. A control signal for the reset transistor 123 is transmitted by the signal line RST.

The amplification transistor 121 amplifies the voltage of the charge holding sections 103a to 103d. The gate of the amplification transistor 121 is connected to the charge holding sections 103a to 103d. Therefore, a pixel signal having a voltage corresponding to the charge held in the charge holding sections 103a to 103d is generated at the source of the amplification transistor 121. Furthermore, the pixel signal can be output to the signal line 92 by making the selection transistor 122 conductive. A control signal for the selection transistor 122 is transmitted by the signal line SEL.

The photoelectric conversion sections 101a to 101d perform photoelectric conversion of incident light during an exposure period to generate a charge and accumulates the charge in itself. After the lapse of the exposure period, the charge transfer sections 102a to 102d transfers the charges of the photoelectric conversion sections 101a to 101d to the charge holding sections 103a to 103d to be held therein. A pixel signal is generated by the pixel circuit 120 on the basis of the charges that are held. Note that a circuit including the amplification transistor 121 and the selection transistor 122 constitutes a signal generation section 129.

### Configuration of Pixel

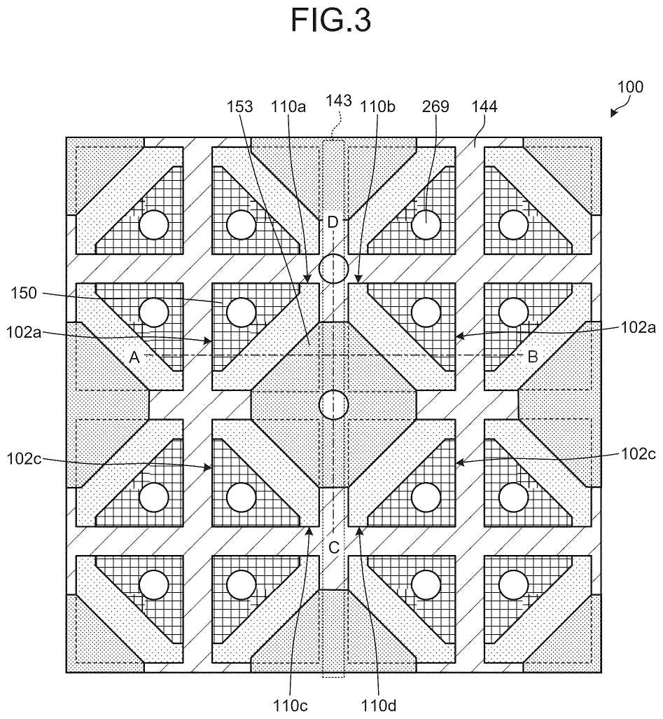

FIG. 3 is a diagram illustrating a structure example of the pixel block according to the first embodiment of the disclosure. The drawing is a plan view illustrating a structure example of pixels 110a to 110d in a pixel block 100. The pixels 110a to 110d are formed in a semiconductor substrate (semiconductor substrate 130 described later). The pixels 110a to 110d are structured to have a square shape in plan view. An isolation section 144 is arranged at boundaries between the pixels 110a to 110d.

Note that a hollow circle in the drawing represents a through wire 269. The through wire 269 is disposed through a semiconductor substrate (semiconductor substrate 230 to be described later) stacked on the semiconductor substrate 130. The through wire 269 disposed at the center of the drawing is connected to a charge holding section common electrode 153. The charge holding section common electrode 153 is an electrode commonly connected to charge holding sections 103a to 103d (not illustrated). Meanwhile, a through wire 269 illustrated above this through wire 269 in the drawing is connected to a well region of the semiconductor substrate 130. As will be described later, the photoelectric conversion section 101 is formed in the vicinity of the back surface of the semiconductor substrate 130.

The charge transfer sections 102a to 102d are arranged at the respective pixels 110a to 110d. In the drawing, a gate electrodes 150 of a MOS transistor included in the charge transfer section 102a and others is illustrated.

Note that a well region electrode 143 to be described later is disposed by being embedded in the isolation section 144 in which the charge holding section common electrode 153 is disposed.

### Structure of Cross-Section of Pixel

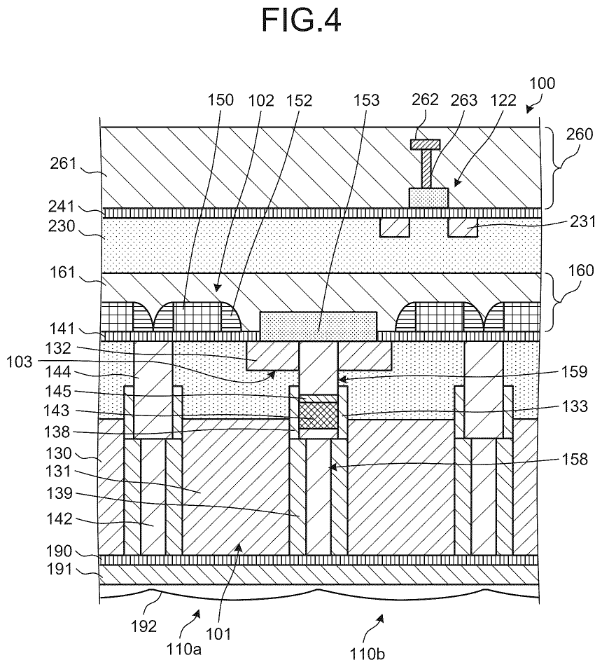

FIG. 4 is a diagram illustrating a structure example of the pixel block according to the first embodiment of the disclosure. The drawing is a cross-sectional view illustrating a structure example of the pixel block 100 in the pixel array section 90. The pixel block 100 in the drawing includes the semiconductor substrate 130, a wiring region 160, the semiconductor substrate 230, a wiring region 260, a color filter 191, and an on-chip lens 192. Note that the pixels 110a and 110b are illustrated in the drawing. The structure of the pixel block 100 will be described by taking the portion of the pixel 110a as an example. Note that FIG. 4 schematically illustrates the shape of a cross section taken along line A-B in FIG. 3.

The semiconductor substrate 130 is a semiconductor substrate in which the photoelectric conversion section 101b and others are arranged. The semiconductor substrate 130 can be made of silicon (Si), for example. The photoelectric conversion section 101b is disposed in a well region formed in the semiconductor substrate 130. For convenience, it is based on the premise that the semiconductor substrate 130 in the drawing includes a p-type well region. An element (diffusion layer thereof) can be formed by arranging n-type and p-type semiconductor region in the p-type well region. A rectangle illustrated in the semiconductor substrate 130 in the drawing represents a semiconductor region.

An isolation section 142 and the isolation section 144 are arranged in the semiconductor substrate 130 at the boundaries between the pixels 110a to 110d. These electrically and optically separate the pixels 110 from each other. The isolation section 144 is an isolation section disposed on the front side of the semiconductor substrate 130. The isolation section 144 is disposed in an opening 159 formed in the semiconductor substrate 130. The isolation section 144 can be made of, for example, silicon oxide (SiO₂).

The isolation section 142 is an isolation section disposed on the back side of the semiconductor substrate 130. The isolation section 142 is disposed in the opening 159 formed in the semiconductor substrate 130. The isolation section 142 can be made of, for example, SiO₂.

A semiconductor region 139 is disposed around the isolation section 142. The semiconductor region 139 is a p-type semiconductor region having a relatively high impurity concentration. By disposing the semiconductor region 139, the surface level of the semiconductor substrate 130 can be pinned. Note that a fixed charge film may be disposed between the semiconductor region 139 and the isolation section 142. The fixed charge film is a film made of a dielectric having a negative fixed charge. A hole accumulation region can be formed in the vicinity of the interface of the semiconductor substrate 130 by the negative fixed charge, whereby the influence of the interface state of the semiconductor substrate 130 can be reduced. This fixed charge film can be made of, for example, hafnium oxide (HfO₂), aluminum oxide (Al₂O₃), or tantalum oxide (Ta₂O₅).

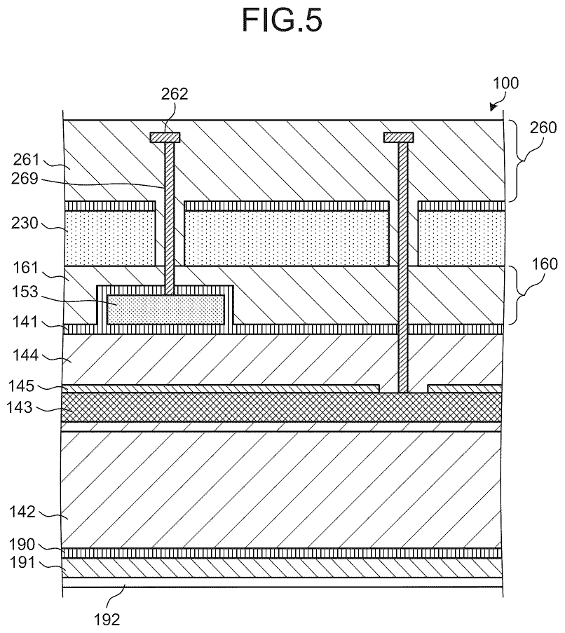

A well region electrode 143 embedded in the semiconductor substrate 130 is disposed in the isolation section 144. The well region electrode 143 is connected to the well region of the semiconductor substrate 130 and supplies a reference potential. The reference potential is transmitted to the well region electrode 143 by the through wire 269 (FIG. 5). Note that the well region electrode 143 is disposed under a charge holding section 103. The well region electrode 143 can be made of, for example, polycrystalline silicon containing an impurity.

An insulating film 145 is disposed on the well region electrode 143. The insulating film 145 corresponds to a stopper film at the time of processing the opening in which the through wire 269 is disposed. The insulating film 145 can be made of, for example, SiN.

A photoelectric conversion section 101 includes an n-type semiconductor region 131. Specifically, a photodiode including a p-n junction formed at an interface between the n-type semiconductor region 131 and the surrounding p-type semiconductor region or well region corresponds to a photoelectric conversion section 101.

The charge holding section 103 includes an n-type semiconductor region 132 having a relatively high impurity concentration. The n-type semiconductor region 132 is referred to as a floating diffusion region. The charge holding section 103 in the drawing is disposed in the vicinity of the front surface of the semiconductor substrate 130. Semiconductor regions 132 of the charge holding sections 103a to 103d are commonly connected by the charge holding section common electrode 153. The charge holding section common electrode 153 can be made of, for example, polycrystalline silicon containing an impurity.

Furthermore, the charge transfer section 102 is disposed in proximity to the isolation section 142 at a corner portion of the pixel 110. As described above, the charge transfer section 102 includes the gate electrode 150. When an ON voltage is applied to the gate electrode 150, a channel is formed in the well region adjacent to the gate electrode 150, and the photoelectric conversion section 101 and the charge holding section 103 are electrically connected to each other. As a result, the charge accumulated in the photoelectric conversion section 101 is transferred to the charge holding section 103. Note that the gate electrode 150 can be made of polycrystalline silicon containing an impurity. A sidewall 152 is disposed at the gate electrode 150 in the drawing. The sidewall 152 is made of an insulator attached to a side surface of the gate electrode 150.

A semiconductor region 133 is disposed in a region adjacent to the well region electrode 143 in the semiconductor substrate 130. The semiconductor region 133 has a relatively high impurity concentration. By disposing the semiconductor region 133, the resistance with the well region electrode 143 can be reduced.

Insulating films 141 and 190 are disposed on the front surface and the back surface of the semiconductor substrate 130, respectively. The insulating films 141 and 190 can be made of, for example, silicon oxide (SiO₂) or silicon nitride (SiN). Note that an insulating film is also disposed between the gate electrode 150 and others and the semiconductor substrate 130. The insulating film corresponds to a gate insulating film.

The wiring region 160 is disposed on the front surface of the semiconductor substrate 130 and is a region in which wiring that transmits a signal or the like of an element is disposed. The wiring region 160 in the drawing includes an insulating layer 161. The insulating layer 161 insulates the gate electrode 150, wires, and others arranged on the surface of the semiconductor substrate 130. The insulating layer 161 can be made of, for example, SiO₂.

The semiconductor substrate 230 is a substrate made of a semiconductor in which the pixel circuits 120 are arranged. The semiconductor substrate 230 is stacked on the semiconductor substrate 130. The back surface of the semiconductor substrate 230 is bonded to the surface of the wiring region 160 of the semiconductor substrate 130, whereby the semiconductor substrates 130 and 230 are stacked. Similarly to the semiconductor substrate 130, the semiconductor substrate 230 can be made of Si.

As described above, the pixel circuit 120 is disposed in the semiconductor substrate 230. The selection transistor 122 of the pixel circuit 120 is illustrated on the semiconductor substrate 230 in the drawing. The semiconductor elements of the pixel circuit 120 are formed by a semiconductor region 231 or a gate electrode formed in the semiconductor substrate 230. In addition, an insulating film 241 is disposed on the front surface of the semiconductor substrate 230.

The wiring region 260 is disposed on the front surface of the semiconductor substrate 230. The wiring region 260 includes a wire 262, a contact plug 263, and an insulating layer 261.

Similarly to the insulating layer 161, the insulating layer 261 insulates wiring and others. The insulating layer 261 can be made of, for example, SiO₂. The wire 262 transmits a signal or the like to an element in the pixel block 100. The wire 262 can be made of metal such as copper (Cu) or W. The contact plug 263 electrically connects the wiring and a member in the semiconductor substrate. The contact plug 253 can be made of, for example, W or the like in a columnar shape.

The color filter 191 is an optical filter that transmits light having a predetermined wavelength in incident light. As the color filter 191, color filters that transmit red light, green light, or blue light can be used.

The on-chip lens 192 condenses incident light. The on-chip lens 192 is formed in, for example, a hemispherical shape and condenses incident light on the photoelectric conversion section 101 and others.

FIG. 5 is a diagram illustrating a structure example of the pixel block according to the first embodiment of the disclosure. The drawing is, similarly to FIG. 4, a cross-sectional view illustrating a structure example of the pixel block 100 in the pixel array section 90. FIG. 5 is a diagram schematically illustrating the shape of a cross section taken along line C-D in FIG. 3.

As described above, the through wire 269 connects the charge holding section common electrode 153 and others of the semiconductor substrate 130 and the wire 262 of the semiconductor substrate 230. The through wire 269 is formed in a shape penetrating the semiconductor substrate 230. Specifically, the through wire 269 is disposed in an opening penetrating the semiconductor substrate 230 and is insulated from the semiconductor substrate 230 by an insulating layer 251. Note that the through wire 269 is also connected to the well region electrode 143.

As illustrated in the drawing, the well region electrode 143 is disposed along a boundary between pixels 110. The reference potential is supplied to the well region of the semiconductor substrate 130 in contact with the well region electrode 143 via the semiconductor region 133. As a result, the substrate potential of the semiconductor substrate 130 can be fixed.

As described above, a pixel 110 is separated from an adjacent pixel 110 by the isolation sections 142 and 144. Therefore, it is necessary to supply the reference potential to each pixel 110. However, disposing the through wire 269 serving as a supply path of the reference potential to each pixel 110 brings about an increase of the size (area) of the pixels 110, which makes miniaturization difficult. However, the size of the pixels 110 can be reduced by arranging the well region electrode 143 for transmitting the reference potential in the isolation section 144 at the boundary of the pixels 110 and allowing the well region electrode 143 to be shared among the adjacent pixels 110.

In addition, by disposing the well region electrode 143 embedded in the isolation section 144, it is possible to expand a region where other components such as the charge transfer section 102 or the charge holding section 103 are arranged to the surface of the semiconductor substrate 130. As a result, the charge transfer section 102 and the charge holding section 103 can be arranged apart from each other, and concentration of the electric field in the vicinity of the gate electrode 150 of the charge transfer section 102 can be relaxed. Therefore, it is possible to reduce defects caused by the concentration of the electric field such as occurrence of white spots. In addition, a channel of the charge transfer section 102 can be expanded, whereby the charge transfer characteristics of the photoelectric conversion section 101 can be improved. For example, the short channel effect of the charge transfer section 102 can be reduced.

It is also possible to reduce the number of through wires 269 that transmit the reference potential, and thus the region where the pixel circuit 120 is disposed can be expanded also in the semiconductor substrate 230.

### Manufacturing Method of Imaging Element

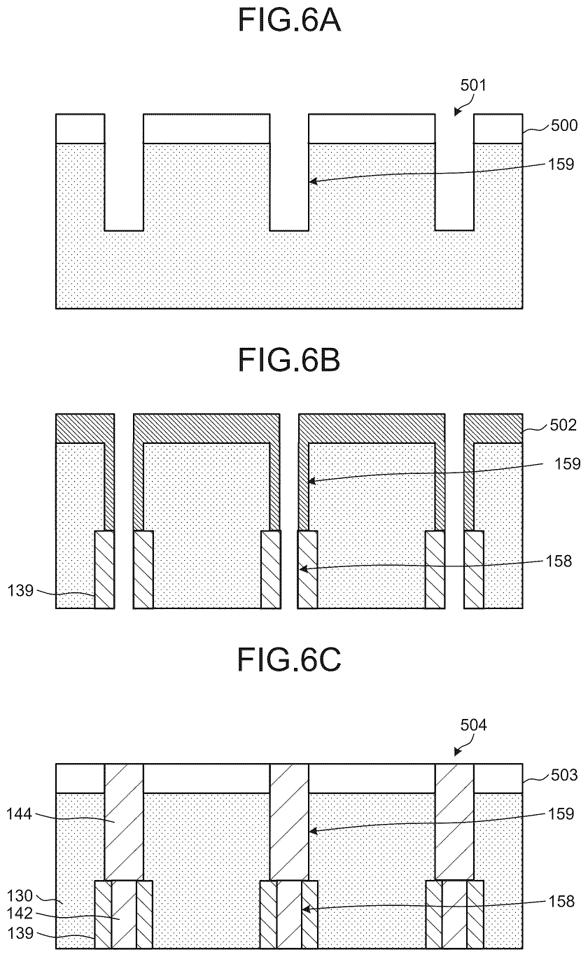

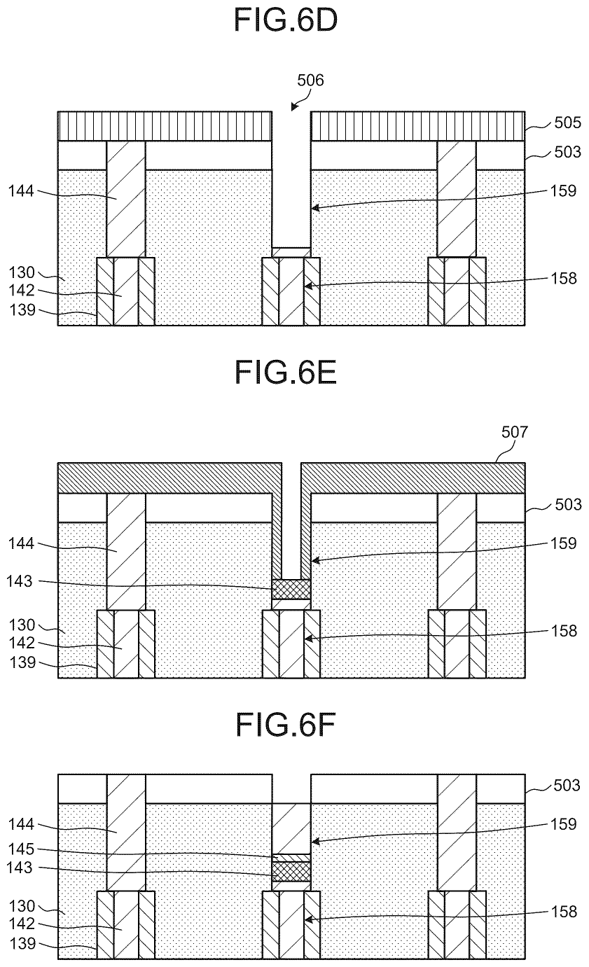

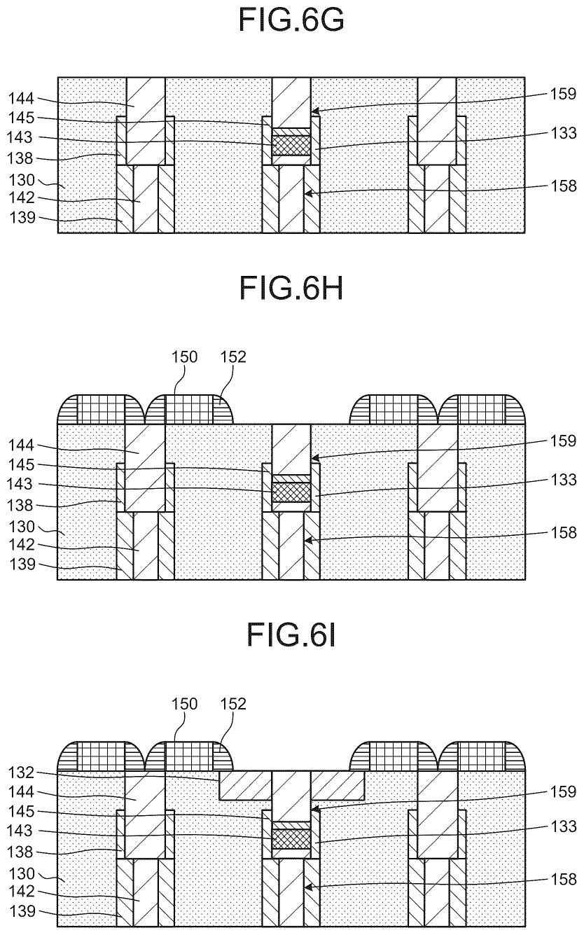

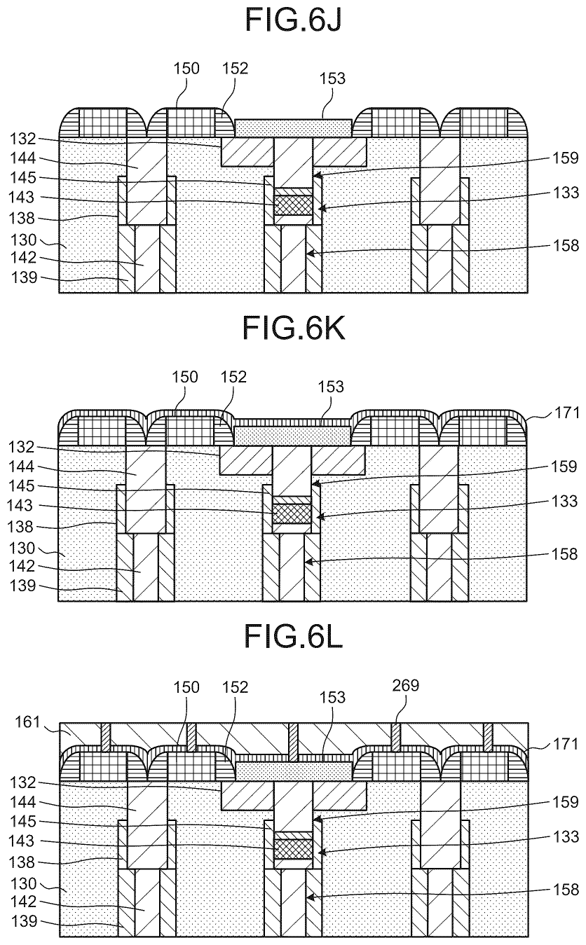

FIG. 6A to 6L are diagrams illustrating an example of the manufacturing method of the imaging element according to the first embodiment of the disclosure. The drawings illustrate an example of the manufacturing method of a pixel block 100 in the imaging element 1. The manufacturing process of the pixel block 100 will be described with reference to the drawings.

First, a hard mask 500 is disposed on the semiconductor substrate 130 in which a semiconductor region 131 of a photoelectric conversion section 101 is formed. In the hard mask 500, openings 501 are arranged at regions where openings 159 are to be formed. Next, the semiconductor substrate 130 is etched to form the openings 159 (FIG. 6A).

Next, an SiN film 502 is disposed on the surface of the semiconductor substrate 130 including the openings 159. Then, openings 158 are formed at the bottoms of the openings 159. Next, an impurity is implanted to the semiconductor substrate 130 on the side surfaces of the openings 158 to form semiconductor regions 139 (FIG. 6B).

Next, the SiN film 502 is removed. Subsequently, the isolation sections 142 and 144 are formed. This can be performed by, for example, disposing a film of a component of the isolation sections 142 and 144 on the surface of the semiconductor substrate 130 including the openings 158 and 159 and grinding the surface of the semiconductor substrate 130 (FIG. 6C). For this grinding, chemical mechanical polishing (CMP) can be adopted.

Next, a resist 505 is disposed on the semiconductor substrate 130. In the resist 505, an opening 506 is disposed at a region of the opening 159 in which a well region electrode 143 is to be arranged. Next, using the resist 505 as a mask, the isolation section 144 of the opening 159 is removed by etch-back (FIG. 6D).

Next, the well region electrode 143 is formed. For example, the well region electrode 143 can be formed by disposing a film of a component of the well region electrode 143 on the surface of the semiconductor substrate 130 including the opening 159 and performing etch-back. Then, the SiN film 507 is disposed. Next, an impurity is implanted into the well region electrode 143 using the SiN film 507 as a mask (FIG. 6E).

Subsequently, the SiN film 507 is removed, and the insulating film 145 and the isolation section 144 are sequentially stacked in the opening 159 (FIG. 6F).

Next, the hard mask 503 is removed, and the surface of the semiconductor substrate 130 is ground to be flat. Next, a semiconductor region 133 is formed in the semiconductor substrate 130. This can be performed by ion implantation (FIG. 6G).

Next, gate electrodes 150 are formed. This can be performed by disposing a film of a component of the gate electrodes 150 on the surface of the semiconductor substrate 130 and removing the region other than the gate electrodes 150. Next, sidewalls 152 are formed. For example, a sidewall 152 can be disposed by disposing a film of a component of the sidewall 152 on the surface of the semiconductor substrate 130 and performing etch back (FIG. 6H).

Next, a semiconductor region 132 of a charge holding section 103 is formed. This can be performed by ion implantation (FIG. 6I).

Next, an SiO₂ film (not illustrated) serving as a processing stopper film is disposed. In the SiO₂ film, an opening is formed at a region where a charge holding section common electrode 153 is to be formed. Next, the charge holding section common electrode 153 is formed. This can be performed by disposing a film of a component of the charge holding section common electrode 153 and removing the region other than the charge holding section common electrode 153. Next, an impurity is implanted into the charge holding section common electrode 153 to form a conductor (FIG. 6J).

Next, an SiN film 171 is disposed on the surface of the semiconductor substrate 130. Next, openings are formed in the SiN film 171 at regions where through wires 269 are to be arranged, and the wiring region 160 is disposed. Next, the through wires 269 are formed (FIG. 6L).

Then, the semiconductor substrate 230 is stacked, and the back side of the semiconductor substrate 130 is ground to be thinned. Next, the back surface side of the semiconductor substrate 130 is processed. With the above process, the pixel block 100 can be manufactured.

As described above, in the imaging element 1 according to the first embodiment of the present disclosure, the well region electrode 143 to which the through wire 269 that supplies the reference potential to the well region of the semiconductor substrate 130 of the pixel 110 is connected is disposed in the isolation section 144 at a boundary of the pixel 110. As a result, the size (area) of the pixel 110 can be easily reduced.

### 2. Modifications of First Embodiment

Next, modifications of the first embodiment described above will be described.

### First Modification

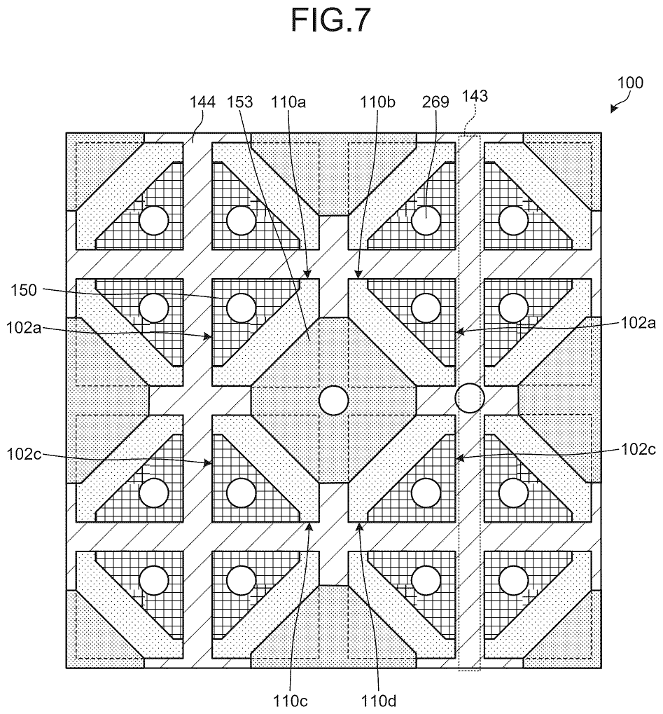

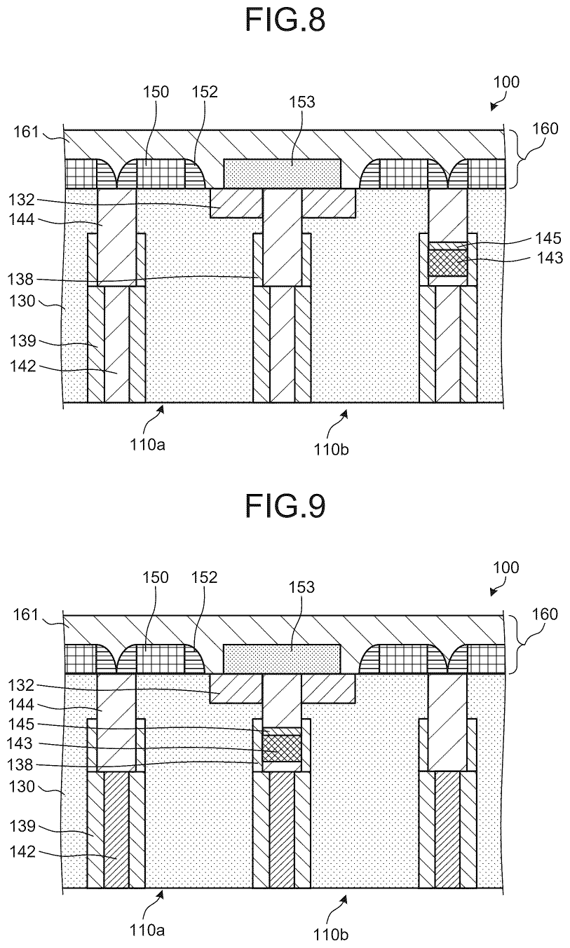

FIGS. 7 and 8 are diagrams illustrating a structure example of a pixel block according to a first modification of the first embodiment of the disclosure. FIG. 7 illustrates a planar structure of a pixel block 100, and FIG. 8 illustrates a cross-sectional structure of the pixel block 100. FIGS. 7 and 8 are diagrams illustrating an example in which, in the pixel block 100, a well region electrode 143 is disposed in an isolation section 144 of a side where charge transfer sections 102 of adjacent pixels 110 are arranged to face each other.

### Second Modification

FIG. 9 is a diagram illustrating a structure example of a pixel block according to a second modification of the first embodiment of the disclosure. The drawing is a cross-sectional view illustrating a structure example of a pixel block 100 of the drawing similarly to FIG. 4. The pixel 110 in the drawing illustrates an example in which an isolation section 142 made of polycrystalline silicon containing an impurity is disposed. A negative bias voltage can be applied to the isolation section 142 in the drawing.

### Third Modification

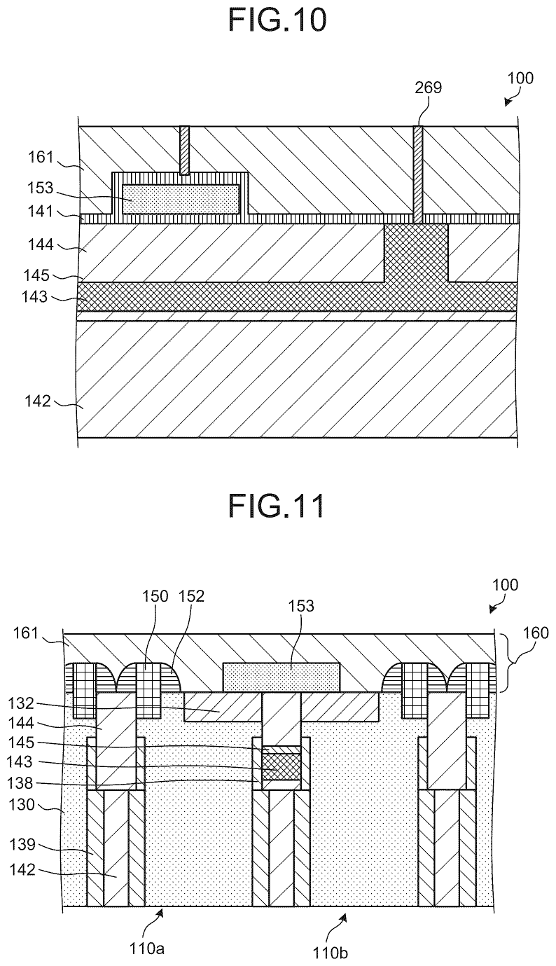

FIG. 10 is a diagram illustrating a structure example of a pixel block according to a third modification of the first embodiment of the disclosure. The drawing is a schematic cross-sectional view illustrating a structure example of a pixel block 100 of the drawing similarly to FIG. 5. A pixel 110 in the drawing illustrates an example in which a well region electrode 143 in a region connected with a through wire 269 has a shape extending to the vicinity of the surface of the semiconductor substrate 130.

### Fourth Modification

FIG. 11 is a diagram illustrating a structure example of a pixel block according to a fourth modification of the first embodiment of the disclosure. The drawing is a cross-sectional view illustrating a structure example of a pixel block 100 of the drawing similarly to FIG. 4. A pixel 110 in the drawing illustrates an example of using a charge transfer section 102 including a MOS transistor having a vertical transfer gate that transfers a charge in the thickness direction of the semiconductor substrate 130. By disposing the charge transfer section 102 in the drawing, the region of a charge holding section 103 on the surface of the pixel 110 can be expanded.

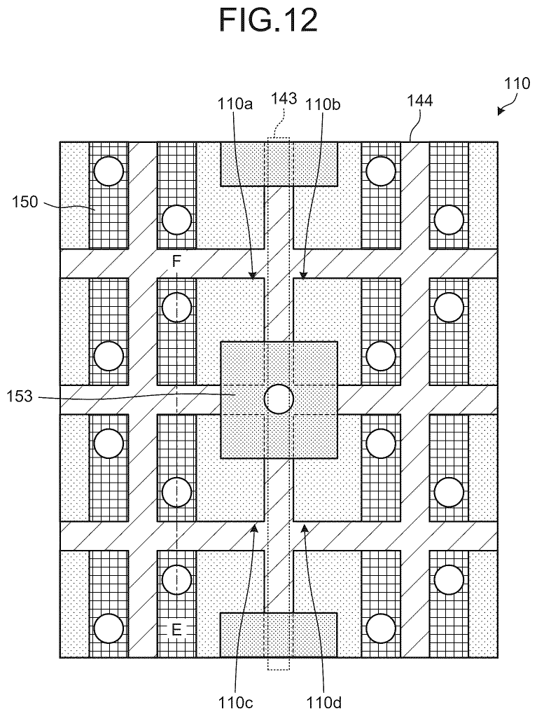

FIG. 12 is a diagram illustrating a structure example of a pixel block according to a fourth modification of the first embodiment of the disclosure. The drawing illustrates a structure example of a pixel block 100 of the drawing similarly to FIG. 3. A charge transfer section 102 in the drawing includes a MOS transistor having a vertical transfer gate as described above. Incidentally, gate electrodes 150 in the drawing represent an example of being in a rectangular shape in plan view.

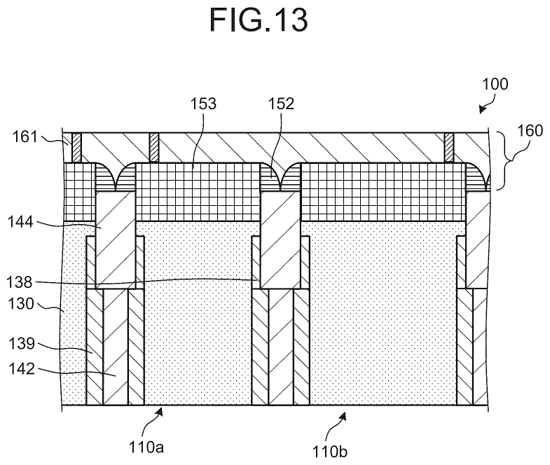

FIG. 13 is a diagram illustrating a structure example of the pixel block according to the fourth modification of the first embodiment of the disclosure. The drawing is a cross-sectional view taken along line E-F of the pixel block 100 in FIG. 12.

### Fifth Modification

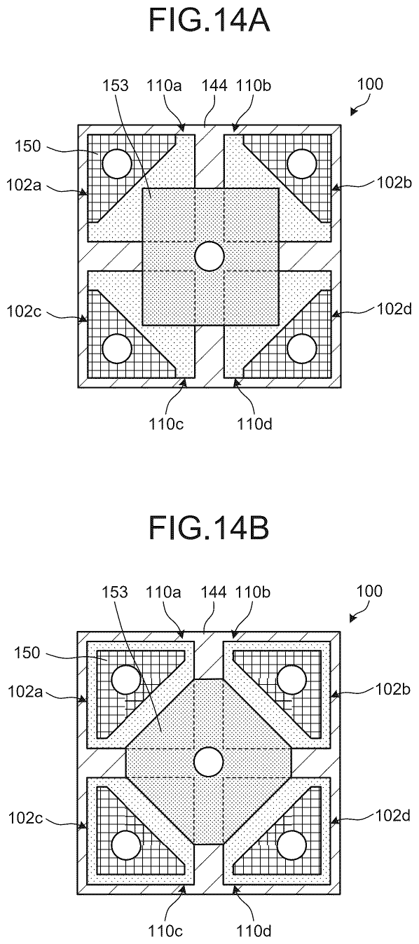

FIGS. 14A and 14B are diagrams illustrating structure examples of a pixel block according to a fifth modification of the first embodiment of the disclosure. The drawing illustrates a structure example of a pixel block 100 of the drawing similarly to FIG. 3. The pixel block 100 in FIG. 14A illustrates an example in which a charge holding section common electrode 153 having a rectangular shape is disposed. FIG. 14B is a diagram illustrating an example of charge transfer sections 102 arranged apart from boundaries of pixels 110.

### Sixth Modification

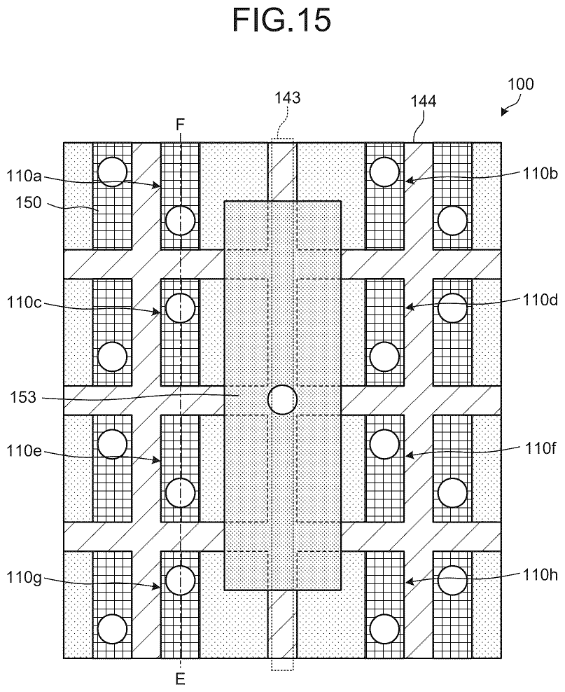

FIG. 15 is a diagram illustrating a structure example of a pixel block according to a sixth modification of the first embodiment of the disclosure. The drawing is a plan view illustrating a structure example of a pixel block 100 of the drawing similarly to FIG. 3. The pixel block 100 in the drawing illustrates an example in which eight pixels 110 of pixels 110a to 110h are included. The pixels 110a to 110h are connected to one pixel circuit 120. The charge holding section common electrode 153 in the drawing can be formed in a shape commonly connected to charge holding sections 103 of the pixels 110a to 110h.

### Seventh Modification

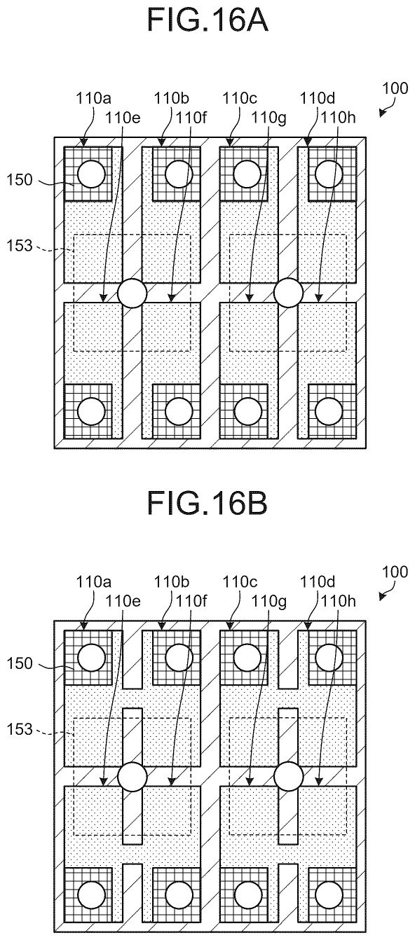

FIGS. 16A and 16B are diagrams illustrating structure examples of a pixel block according to a seventh modification of the first embodiment of the disclosure. The drawings are, similarly to FIG. 15, plan views illustrating an example of a pixel block 100 including eight pixels 110 of pixels 110a to 110h. Note that, in the drawing, a dotted rectangle represents a charge holding section common electrode 153. In FIG. 16A, the pixel 110a and the pixel 110b are formed to have a rectangular shape obtained by dividing a square into two. The pixel 110a and the pixel 110b can be used as phase difference pixels for detecting an image plane phase difference. Furthermore, in a case where a normal image signal is generated, charges generated by photoelectric conversion of the pixel 110a and the pixel 110b are simultaneously transferred to the charge holding section 103 to generate a pixel signal. Note that FIG. 16B illustrates an example in which a pixel 110a, a pixel 110b, and others are separated by an isolation section 144 having notches in the central portion.

### Eighth Modification

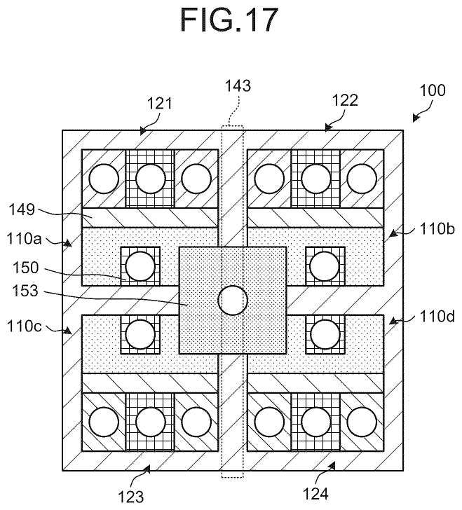

FIG. 17 is a diagram illustrating a structure example of a pixel block according to an eighth modification of the first embodiment of the disclosure. The drawing is a plan view illustrating a structure example of a pixel block 100 of the drawing similarly to FIG. 3. The drawing illustrates an example of the pixel block 100 formed in the semiconductor substrate 130. An amplification transistor 121 is disposed in a pixel 110a in the drawing. Meanwhile, a selection transistor 122 is disposed in a pixel 110b. Furthermore, a reset transistor 123 is disposed in a pixel 110c. Meanwhile, a coupling transistor 124 is disposed in a pixel 110d. An isolation region 149 is disposed between the elements of the pixel circuit 120 and a charge holding section 103. The isolation region 149 can be formed of an insulating member in which a shallow groove-shaped opening is disposed. Also in the pixel block 100 in the drawing, a well region electrode 143 is disposed by being embedded in an isolation section 144.

The configuration of the imaging element 1 other than the above is similar to the configuration of the imaging element 1 in the first embodiment of the present disclosure, and thus description thereof is omitted.

### 3. Second Embodiment

In the imaging element 1 of the first embodiment described above, the charge transfer sections 102 are arranged on the surface of the semiconductor substrate 130. Meanwhile, an imaging element 1 according to a second embodiment of the present disclosure is different from the first embodiment in that charge transfer sections 102 are arranged by being embedded in a semiconductor substrate 130.

### Configuration of Imaging Device

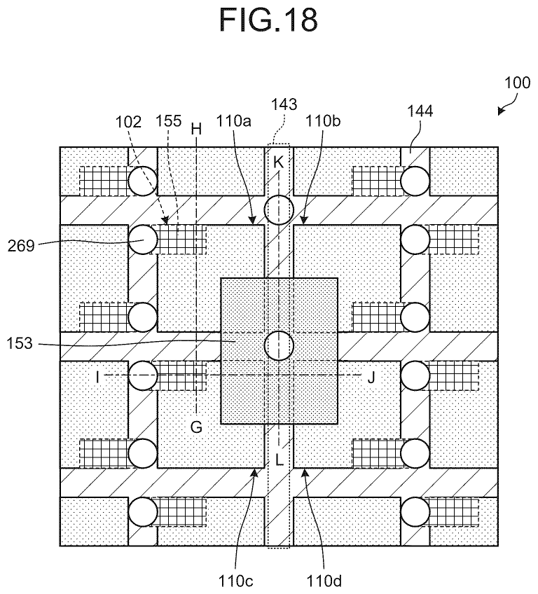

FIG. 18 is a diagram illustrating a structure example of a pixel block according to the second embodiment of the disclosure. The drawing is a plan view illustrating a structure example of a pixel block 100 similarly to FIG. 3. A charge transfer section 102 in the drawing is different from that of the pixel block 100 in FIG. 3 in that the charge transfer section 102 is disposed by being embedded in the semiconductor substrate 130. The charge transfer section 102 includes a gate electrode 155. A broken-line rectangle in the drawing represents a gate electrode 155. The gate electrode 155 has a shape embedded in the semiconductor substrate 130. The gate electrode 155 is disposed adjacent to an isolation section 144. Also in the pixel block 100 in the drawing, a well region electrode 143 is disposed by being embedded in the isolation section 144 at a boundary of pixels 110.

### Configuration of Imaging Device

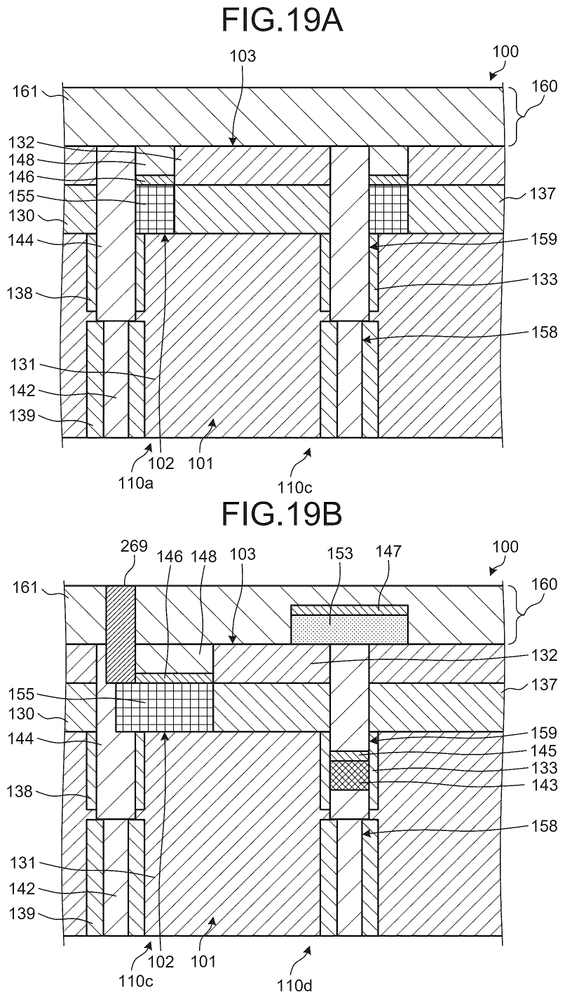

FIGS. 19A and 19B are diagrams illustrating a structure example of the pixel block according to the second embodiment of the disclosure. The drawings are cross-sectional views illustrating a structure example of the pixel block 100 illustrated in FIG. 18. FIG. 19A is a diagram schematically illustrating the shape of a cross section taken along line G-H in FIG. 18. FIG. 19B is a diagram schematically illustrating the shape of a cross section taken along line I-J in FIG. 17.

A semiconductor region 131 of a photoelectric conversion section 101 in the drawings is arranged from the back surface to the vicinity of the front surface of the semiconductor substrate 130. Furthermore, a semiconductor region 132 of a charge holding section 103 is disposed on the front surface of the semiconductor substrate 130 and has a shape that occupies a wide portion of the surface of the pixel 110. A semiconductor region 137 is disposed between the semiconductor regions 131 and 132. The semiconductor region 137 is formed into a p-type and separates the semiconductor regions 131 and 132. The semiconductor region 137 corresponds to a well region.

As described above, the charge transfer section 102 in the drawing has a shape embedded in the semiconductor substrate 130. Specifically, the charge transfer section 102 in the drawing is disposed under a surface of the semiconductor substrate 130 in contact with a wiring region 160. A gate electrode 155 is disposed adjacent to the semiconductor region 137. A channel is formed in the semiconductor region 137 adjacent to the gate electrode 155. In this manner, the charge transfer section 102 in the drawing constitutes a MOS transistor having a vertical transfer gate. Furthermore, the gate electrode 155 has a shape extending to a boundary region of the pixel 110. A through wire 269 is connected at a portion of the gate electrode 155 extending to the boundary region of the pixel 110. As described above, the charge transfer section 102 in the drawing is disposed adjacent to the isolation section 144. Note that the through wire 269 in the drawing is an example of a columnar wire.

The gate electrode 155 can be made of, for example, polycrystalline silicon containing an impurity. A donor such as phosphorus (P) can be applied as the impurity of the gate electrode 155. Incidentally, as a gate insulating film, for example, an SiO₂ (or SiON) film can be used. Alternatively, the gate electrode 155 may be made of metal such as tungsten (W). In this case, a high-dielectric-constant (high-k) insulating film can be adopted as the gate insulating film.

An insulating layer 148 is disposed between the front surfaces of the gate electrode 155 and the semiconductor substrate 130. The insulating layer 148 insulates the gate electrode 155. The insulating layer 148 can be made of, for example, SiO₂. In addition, an insulating film 146 may be disposed on the upper surface of the gate electrode 155. The insulating film 146 corresponds to a stopper film at the time of etching processing. The insulating film 146 can be made of, for example, SiN.

A semiconductor region 133 in the drawing can be formed in a shape adjacent to the semiconductor region 131 of the photoelectric conversion section 101 and adjacent to the bottom surface of the gate electrode 155.

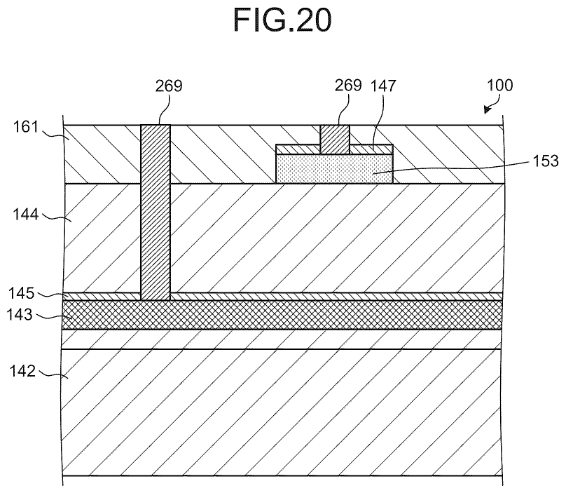

FIG. 20 is a diagram illustrating a structure example of the pixel block according to the second embodiment of the disclosure. The drawing schematically illustrates the shape of a cross section taken along line K-L in FIG. 18. A through wire 269 is connected to the well region electrode 143.

The pixel block 100 of the second embodiment of the present disclosure can allow the size (area) of the pixels 110 to be further reduced with the well region electrode 143 and the charge transfer sections 102 embedded in the semiconductor substrate 130. Furthermore, the charge transfer section 102 and the charge holding section 103 can also be arranged apart from each other. In this case, concentration of the electric field in the vicinity of the gate electrode 155 of the charge transfer section 102 can be relaxed. Therefore, it is possible to reduce defects caused by the concentration of the electric field such as occurrence of white spots. Furthermore, since the gate electrode 155 of the charge transfer section 102 is configured as a vertical transfer gate, an increase in the occupied area on the surface of the pixel 110 can be prevented even in a case where the channel length is extended. Therefore, the channel length of the charge transfer section 102 can be easily adjusted, whereby the charge transfer range can be expanded.

### Manufacturing Method of Imaging Element

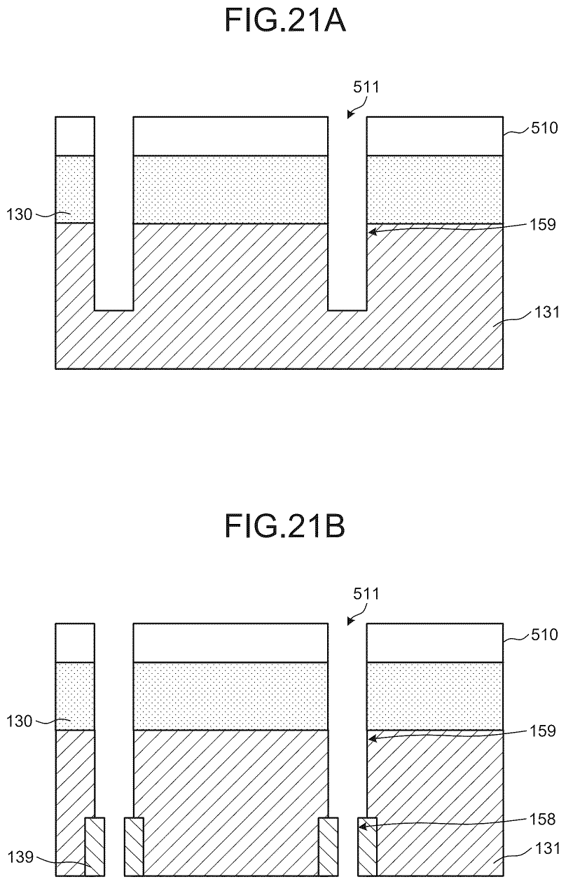

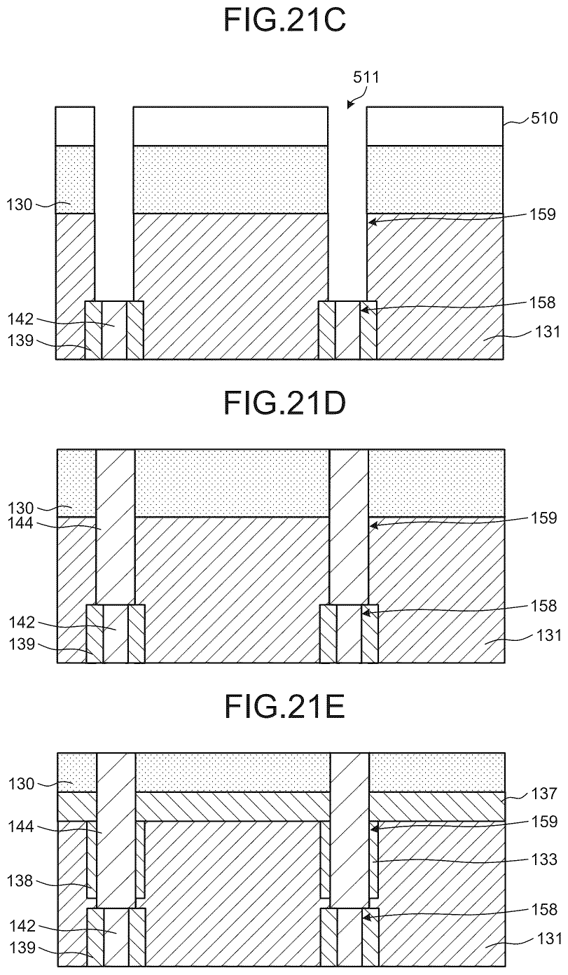

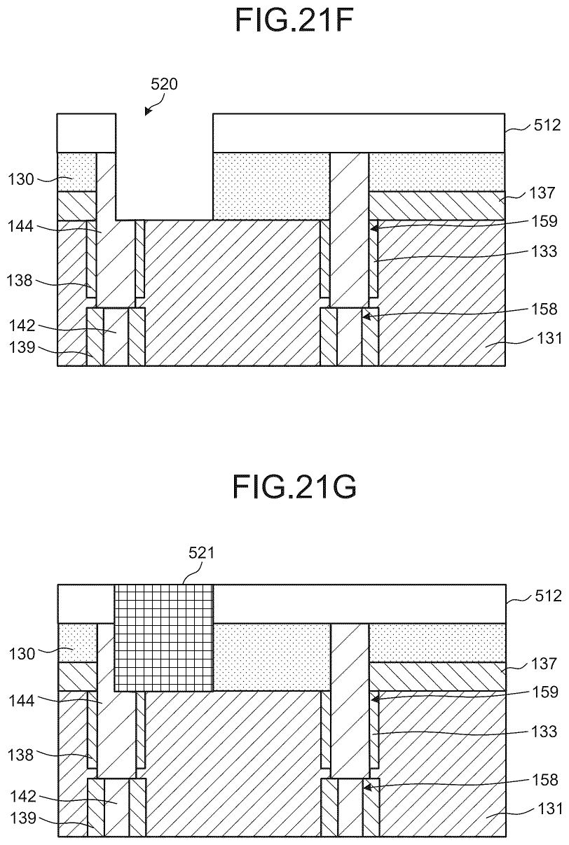

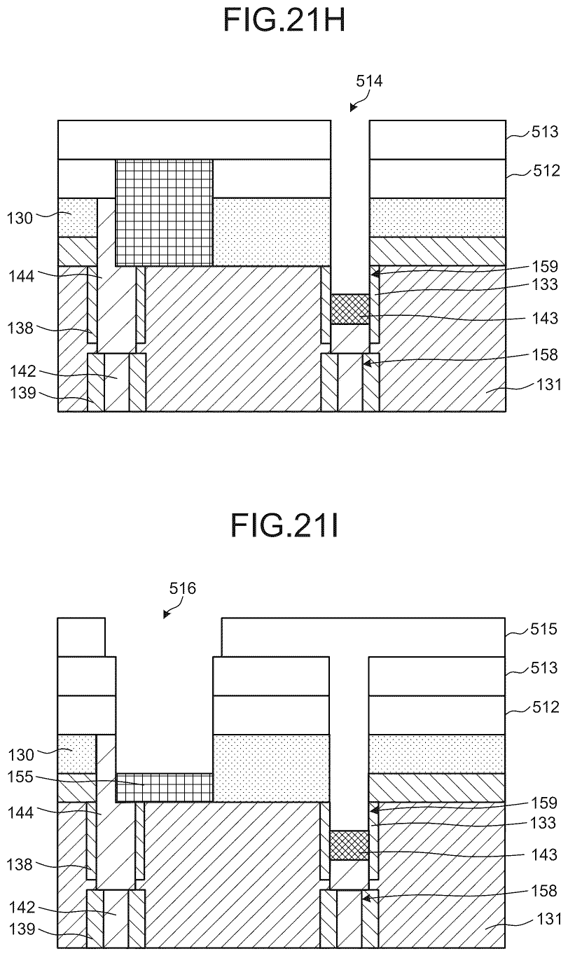

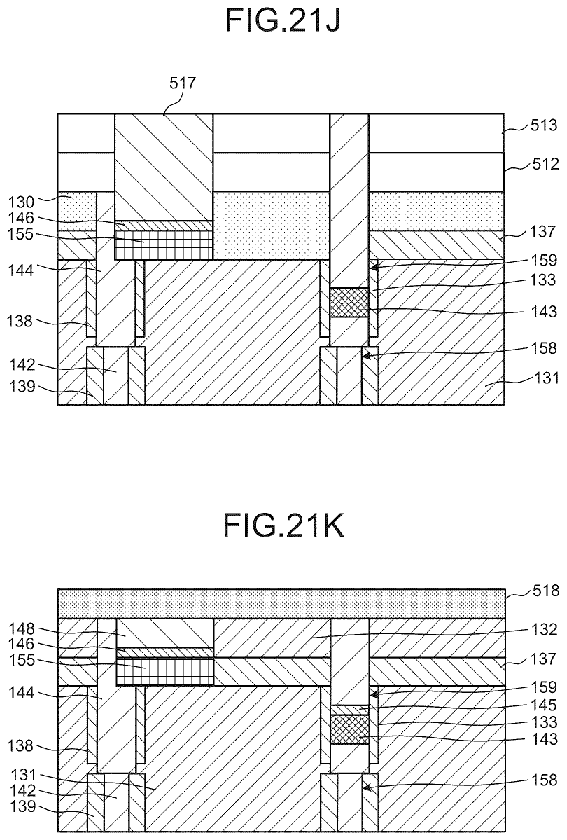

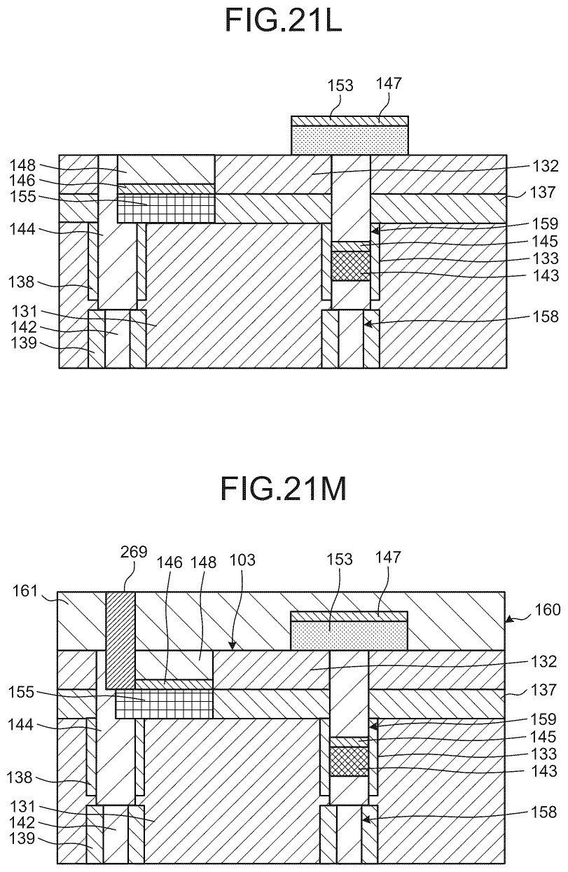

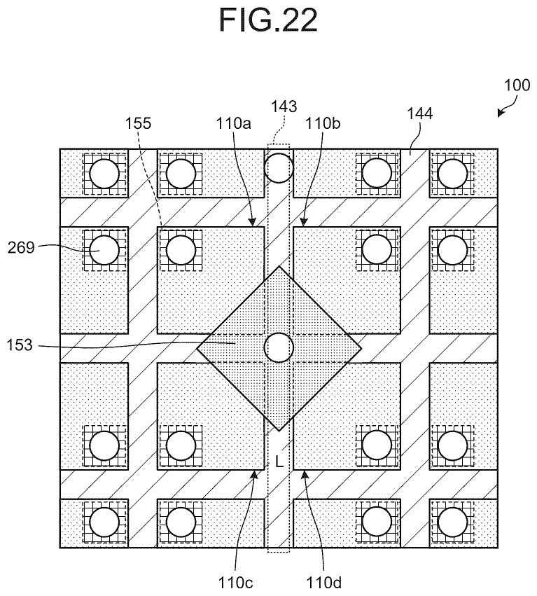

FIG. 21A to 21M are diagrams illustrating an example of the manufacturing method of the imaging element according to the second embodiment of the disclosure. The drawings illustrate an example of the manufacturing process of a pixel block 100 in the imaging element 1.

First, a semiconductor region 131 of a photoelectric conversion section 101 is formed in the semiconductor substrate 130. This can be performed by ion implantation, for example. Next, a hard mask 510 made of SiN or the like is disposed on the semiconductor substrate 130. In the hard mask 500, openings 511 are arranged at regions where openings 159 are to be formed. Next, the semiconductor substrate 130 is etched to form the openings 159 (FIG. 21A).

Subsequently, the SiN film 502 described with reference to FIG. 6B is disposed to form openings 158. Next, semiconductor regions 139 are formed by solid-phase diffusion or plasma doping. Then, the SiN film 502 is removed (FIG. 21B).

Next, sidewalls of the openings 158 and 159 are oxidized. Then, polycrystalline silicon is embedded in the openings 158 and 159. Subsequently, the embedded polycrystalline silicon is etched back to dispose the polycrystalline silicon in the portion of the openings 158. The polycrystalline silicon is removed in a process on the back surface side of the semiconductor substrate 130. For convenience, in the following processes, the isolation section 142 having the same hatching as that in FIG. 19A and others is illustrated (FIG. 21C).

Next, the isolation section 144 is disposed in the openings 159. This can be performed by disposing a component of the isolation section 144 (for example, SiO₂) in the openings 159 and on the surface of the semiconductor substrate 130 and grinding the surface of the semiconductor substrate 130. Then, the hard mask 510 is removed (FIG. 21D).

Next, the semiconductor regions 133 and the semiconductor region 137 are formed (FIG. 21E). The semiconductor regions 133 can be formed by disposing a resist having openings along the outer periphery of the openings 159 on the surface of the semiconductor substrate 130 and performing partial ion implantation. In addition, the semiconductor region 137 can be formed by performing ion implantation on the front surface of the semiconductor substrate 130.

Next, a hard mask 512 is disposed on the surface of the semiconductor substrate 130. In the hard mask 512, an opening 520 is disposed at a portion where a gate electrode 155 is to be disposed (FIG. 21F). Next, the semiconductor substrate 130 is etched to form an opening at a region where the gate electrode 155 is to be disposed. Then, the gate insulating film is formed. Next, a components 521 of the gate electrode 155 is embedded in the opening 520. Subsequently, an ion such as P is implanted into the gate electrode 155 (FIG. 21G). In a case where polycrystalline silicon containing an impurity (such as P) is disposed as the component of the gate electrode 155, ion implantation of the gate electrode 155 can be omitted. Note that, after the formation of the opening 520, n-type or p-type ion implantation can also be performed in order to adjust a channel region in generation of a semiconductor region by self-alignment in a subsequent stage.

Next, a hard mask 513 is disposed on the hard mask 512. Then, an openings 514 is formed in the hard masks 512 and 513. Next, etch-back is performed to remove the isolation section 142 other than the vicinity of the bottom portion of the opening 159. Next, a well region electrode 143 is disposed in the opening 159 (FIG. 21H). An impurity (for example, boron (B)) is diffused from the well region electrode 143 to the semiconductor substrate 130 by a thermal process such as a process of the semiconductor substrate 230, and a semiconductor region 133 having a high impurity concentration is formed.

Next, a resist 515 is disposed on the surface of the semiconductor substrate 130 including the opening 514 of the hard mask 512. In the resist 515, an opening 516 is disposed at a region of the gate electrode 155. Next, the component 521 is etched back to form the gate electrode 155 (FIG. 21I).

Then, an insulating film 146 is disposed on the gate electrode 155. Next, a component 517 of the insulating layer 148 is disposed (FIG. 21J).

Subsequently, the hard masks 512 and 513 are removed. Then, a semiconductor region 132 is formed. This can be performed by ion implantation. Next, an oxide film on the surface of the semiconductor substrate 130 is removed, and a film 518 of the component of the charge holding section common electrode 153 is disposed (FIG. 21K).

Next, the film 518 is etched to form the charge holding section common electrode 153. Next, an insulating layer 147 is disposed (FIG. 21L).

Then, the wiring region 160 is disposed, the semiconductor substrate 230 is stacked, and a through wire 269 is formed (FIG. 21M). Then, the back surface process is performed. For example, the polycrystalline silicon of the isolation section 142 is removed, and backfilling with SiO₂ or the like is performed. With the above process, the pixel block 100 can be manufactured.

The configuration of the imaging element 1 other than the above is similar to the configuration of the imaging element 1 in the first embodiment of the present disclosure, and thus description thereof is omitted.

As described above, the imaging element 1 according to the second embodiment of the present disclosure can easily reduce the size (area) of the pixels 110 by embedding the charge transfer sections 102 in the semiconductor substrate 130 in addition to the well region electrodes 143. Furthermore, since the charge transfer sections 102 have a shape embedded in the semiconductor substrate 130, self-aligned ion implantation or entire surface ion implantation can be applied when a semiconductor region or the like of the pixels 110 is formed. The yield of the manufacturing process can be improved.

### 4. Modifications of Second Embodiment

Next, modifications of the second embodiment described above will be described.

### First Modification

FIG. 22 is a diagram illustrating a structure example of a pixel block according to a first modification of the second embodiment of the disclosure. The drawing is a plan view illustrating a structure example of a pixel block 100 similarly to FIG. 18. As illustrated in the drawing, a through wire 269 connected to a well region electrode 143 can also be disposed at a region other than the intersection region of the isolation section 144. In addition, a gate electrode 155 can also be formed in a square shape. Note that gate electrodes 155 can be arranged at desired positions. In addition, a charge holding section common electrode 153 can be formed in any shape other than a rectangle. The drawing illustrates an example in which the charge holding section common electrode 153 is formed in a rhombic shape.

### Second Modification

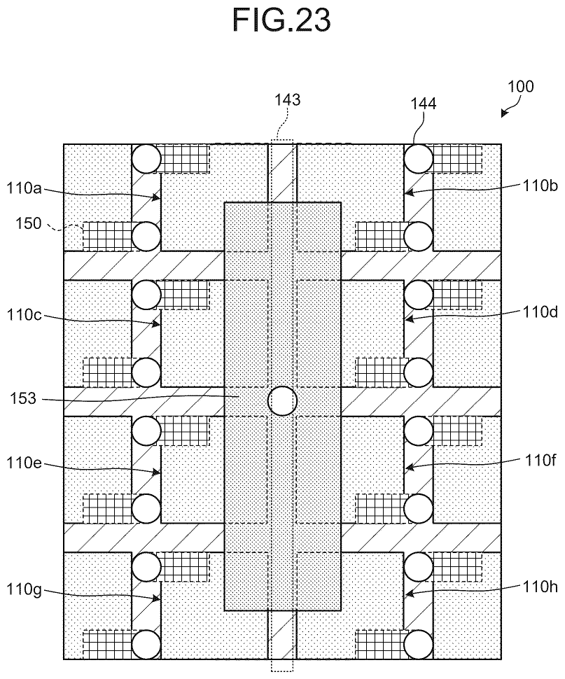

FIG. 23 is a diagram illustrating a structure example of a pixel block according to a second modification of the second embodiment of the disclosure. The drawing is a plan view illustrating a configuration example of a pixel block 100. Furthermore, the drawing illustrates an example of the pixel block 100 including pixels 110a to 110h, similarly to FIG. 15. The charge holding section common electrode 153 in the drawing can be formed in a shape commonly connected to charge holding sections 103 of the pixels 110a to 110h.

### Third Modification

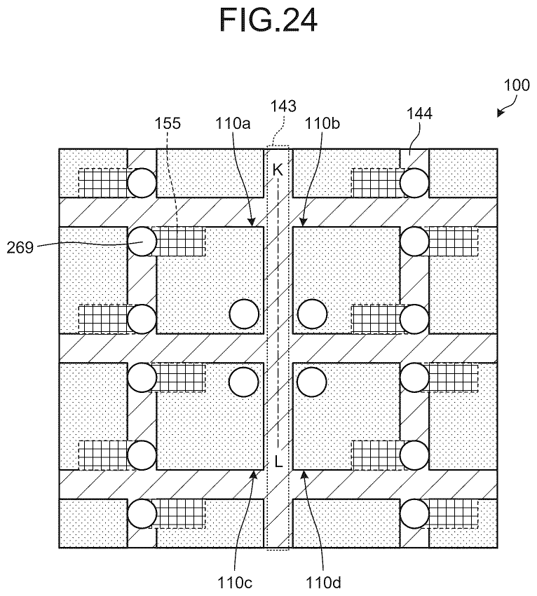

FIG. 24 is a diagram illustrating a structure example of a pixel block according to a third modification of the second embodiment of the disclosure. The drawing is a plan view illustrating a configuration example of a pixel block 100. The drawing illustrates an example in which the charge holding section common electrode 153 is omitted. In the drawing, a through wire 269 is disposed for each charge holding section 103.

### Fourth Modification

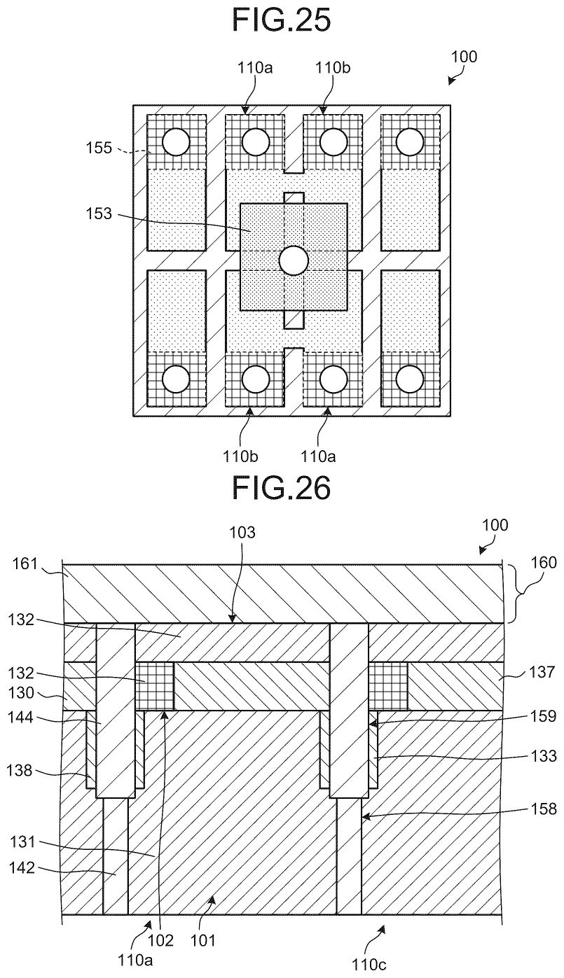

FIG. 25 is a diagram illustrating a structure example of a pixel block according to a fourth modification of the second embodiment of the disclosure. The drawing is a plan view illustrating a configuration example of a pixel block 100. Furthermore, the drawing illustrates an example of the pixel block 100 including pixels 110a to 110h having a rectangular shape, similarly to FIG. 16B. Also in the example of the drawing, charge transfer sections 102 can be embedded in the semiconductor substrate 130. Note that a similar structure to that in FIG. 16A can also be adopted.

### Fifth Modification

FIG. 26 is a diagram illustrating a structure example of a pixel block according to a fifth modification of the second embodiment of the disclosure. The drawing is a cross-sectional view illustrating a structure example of a pixel block 100. This drawing illustrates an example in which the insulating layer 148 on the gate electrode 155 is omitted, and a semiconductor region 132 is disposed by being expanded. Note that openings 158 and 159 at a boundary of a pixel 110 can be formed to have the same width. In this case, the opening shape has no steps. The openings 158 and 159 can be formed by any manufacturing method. For example, the opening 158 can also be formed from the back side of the semiconductor substrate 130.

### Sixth Modification

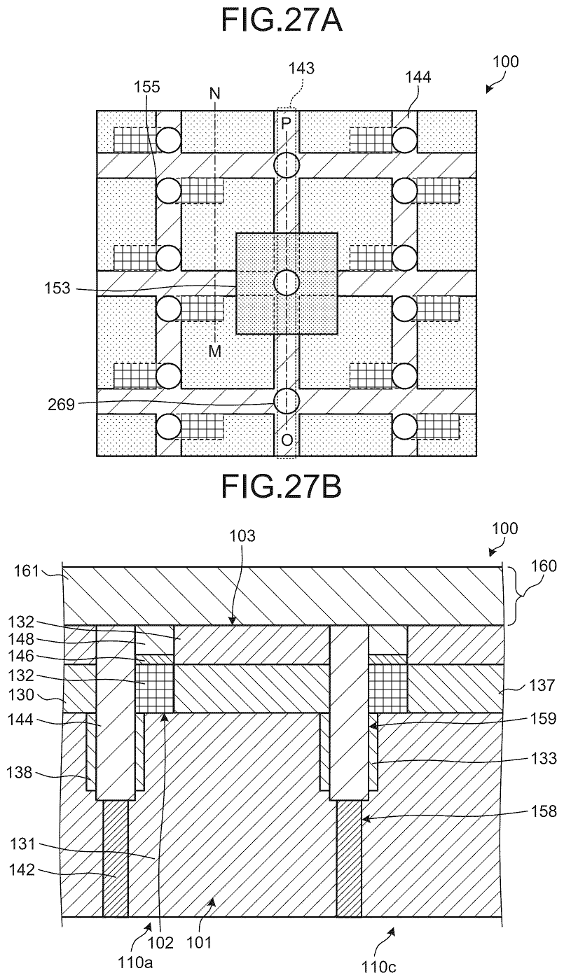

FIGS. 27A and 27B are diagrams illustrating a structure example of a pixel block according to a sixth modification of the second embodiment of the disclosure. FIGS. 27A is a plan view illustrating a structure example of a pixel block 100. Meanwhile, FIG. 27B is a cross-sectional view illustrating a structure example of the pixel block 100. Note that FIG. 27B is a diagram schematically illustrating the shape of a cross section taken along line M-N in FIG. 27A.

An isolation section 142 in FIG. 27B illustrates an example in which the isolation section 142 is formed of a conductive member such as polycrystalline silicon containing an impurity. The isolation section 142 is disposed at a position deeper than the well region electrode 143. A negative bias voltage can be applied to the isolation section 142 in the drawing. As a result, the action of pinning can be improved. A through wire 269 that transmits a negative bias voltage can be disposed at any position inside or outside a pixel 110. Note that the isolation section 142 in the drawing is an example of an isolation section electrode.

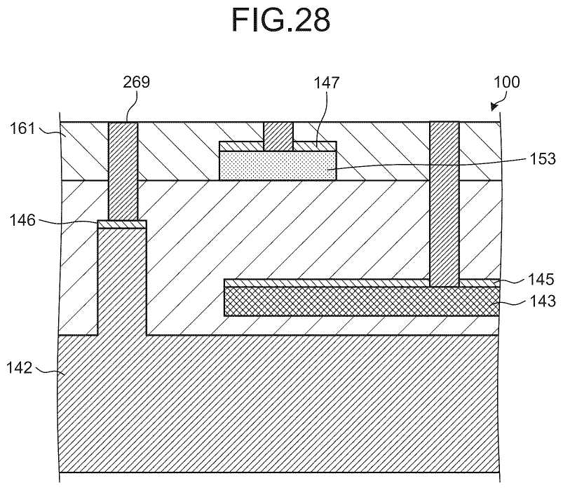

FIG. 28 is a diagram illustrating a structure example of a pixel block according to a sixth modification of the second embodiment of the disclosure. The drawing is a cross-sectional view illustrating a structure example of a pixel block 100. The drawing schematically illustrates the shape of a cross section taken along line O-P in FIG. 27A. A through wire 269 on the left side in the drawing illustrates an example of the through wire 269 that transmits the negative bias voltage described above. The drawing illustrates an example in which a well region electrode 143 in a region connected to a through wire 269 is configured in a shape extending to the vicinity of the surface of the semiconductor substrate 130.

The configuration of the imaging element 1 other than the above is similar to the configuration of the imaging element 1 in the first embodiment of the present disclosure, and thus description thereof is omitted.

### 5. Other Configuration Examples

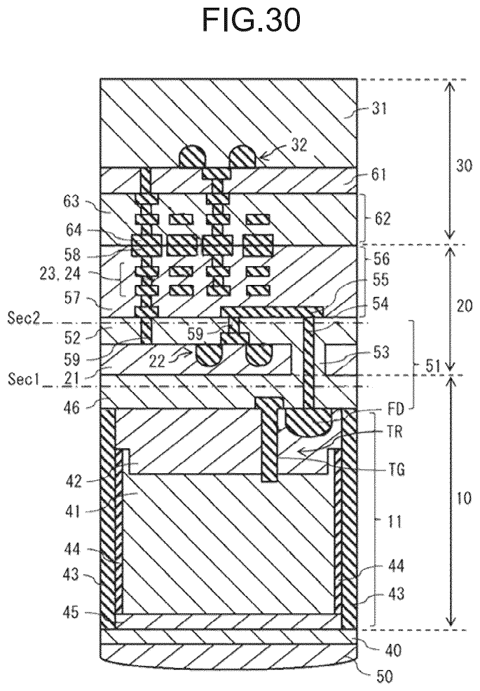

FIG. 30 is a diagram illustrating another configuration example of an imaging element. An imaging element 1 includes three substrates (first substrate 10, second substrate 20, and third substrate 30). The imaging element 1 has a three-dimensional structure formed by bonding the three substrates (first substrate 10, second substrate 20, and third substrate 30). The first substrate 10, the second substrate 20, and the third substrate 30 are stacked in this order.

The first substrate 10 includes, in a semiconductor substrate 11, a plurality of sensor pixels 12 that performs photoelectric conversion. The semiconductor substrate 11 corresponds to a specific example of the “first semiconductor substrate” of the present disclosure. The plurality of sensor pixels 12 is provided in a matrix shape in a pixel region 13 of the first substrate 10. The second substrate 20 includes, in a semiconductor substrate 21, a readout circuit 22 that outputs a pixel signal based on charges output from sensor pixels 12, the readout circuit 22 each provided for every four sensor pixels 12. The semiconductor substrate 21 corresponds to a specific example of the “second semiconductor substrate” of the present disclosure. The second substrate 20 includes a plurality of pixel drive lines 23 extending in the row direction and a plurality of vertical signal lines 24 extending in the column direction. The third substrate 30 includes, in a semiconductor substrate 31, a logic circuit 32 that processes a pixel signal. The semiconductor substrate 31 corresponds to a specific example of the “third semiconductor substrate” of the present disclosure. The logic circuit 32 includes, for example, a vertical drive circuit 33, a column signal processing circuit 34, a horizontal drive circuit 35, and a system control circuit 36. The logic circuit 32 (specifically, the horizontal drive circuit 35) outputs an output voltage Vout for each of the sensor pixels 12 to the outside. In the logic circuit 32, for example, a low resistance region, made of silicide formed using a self-aligned silicide process such as CoSi2 or NiSi, may be formed on a surface of an impurity diffusion region in contact with a source electrode and a drain electrode.

The vertical drive circuit 33 sequentially selects, for example, a plurality of sensor pixels 12 row by row. The column signal processing circuit 34 performs, for example, correlated double sampling (CDS) processing on a pixel signal output from each of the sensor pixels 12 of the row selected by the vertical drive circuit 33. The column signal processing circuit 34 extracts a signal level of a pixel signal by performing, for example, the CDS processing and holds pixel data corresponding to the amount of light received by each of the sensor pixels 12. The horizontal drive circuit 35 sequentially outputs, for example, the pixel data held in the column signal processing circuit 34 to the outside. The system control circuit 36 controls driving of each block (the vertical drive circuit 33, the column signal processing circuit 34, and the horizontal drive circuit 35) in the logic circuit 32, for example.

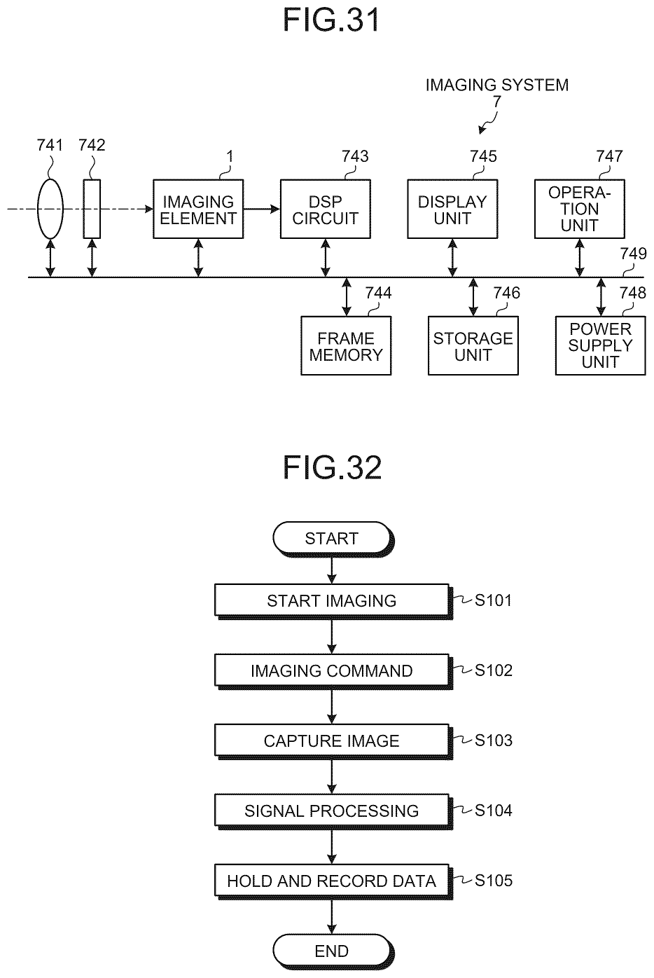

FIG. 31 is a cross-sectional view illustrating another configuration example of the imaging element. The drawing illustrates an example of a cross-sectional structure in the vertical direction of the imaging element 1 in FIG. 30. FIG. 31 illustrates an example of a cross-sectional structure of a portion facing a sensor pixel 12 in the imaging element 1. The imaging element 1 is structured by stacking the first substrate 10, the second substrate 20, and the third substrate 30 in this order and further includes a color filter 40 and a light receiving lens 50 on the back surface side (light incident surface side) of the first substrate 10. For example, one color filter 40 and one light receiving lens 50 are provided for every sensor pixel 12. That is, the imaging element 1 is a back-illuminated type.

The first substrate 10 is formed by stacking an insulating layer 46 on the semiconductor substrate 11. The first substrate 10 includes the insulating layer 46 as a part of an interlayer insulating film 51. The insulating layer 46 is included in a gap between the semiconductor substrate 11 and the semiconductor substrate 21 to be described later. The semiconductor substrate 11 is formed of a silicon substrate. The semiconductor substrate 11 has, for example, a p-well layer 42 at a part of the front surface and in the vicinity thereof and a PD 41 having a conductivity type different from that of the p-well layer 42 in another region (region deeper than the p-well layer 42). The p-well layer 42 is formed of a p-type semiconductor region. The PD 41 is formed of a semiconductor region of a conductivity type (specifically, n-type) different from that of the p-well layer 42. The semiconductor substrate 11 has, in the p-well layer 42, a floating diffusion FD as a semiconductor region of a conductivity type (specifically, n-type) different from that of the p-well layer 42.

The first substrate 10 includes a photodiode PD, a transfer transistor TR, and a floating diffusion FD for each sensor pixel 12. The first substrate 10 has a structure in which the transfer transistor TR and the floating diffusion FD are included in a portion on the front surface side (side opposite to the light incident surface side, second substrate 20 side) of the semiconductor substrate 11. The first substrate 10 includes an element isolation section 43 that isolates each sensor pixel 12. The element isolation section 43 is formed to extend in the normal direction of the semiconductor substrate 11 (direction perpendicular to the front surface of the semiconductor substrate 11). The element isolation section 43 is included between two sensor pixels 12 adjacent to each other. The element isolation section 43 electrically isolates the sensor pixels 12 adjacent to each other from each other. The element isolation section 43 is made of, for example, silicon oxide. The element isolation section 43 penetrates the semiconductor substrate 11, for example. The first substrate 10 further includes a p-well layer 44 that is, for example, a side surface of the element isolation section 43 and is in contact with a surface on the photodiode PD side. The p-well layer 44 is formed of a semiconductor region of a conductivity type (specifically, p-type) different from that of the photodiode PD. The first substrate 10 further includes, for example, a fixed charge film 45 in contact with the back surface of the semiconductor substrate 11. The fixed charge film 45 is negatively charged in order to suppress generation of a dark current caused by an interface state on the light-receiving surface side of the semiconductor substrate 11. The fixed charge film 45 is formed of, for example, an insulating film having a negative fixed charge. Examples of the material of such an insulating film include hafnium oxide, zircon oxide, aluminum oxide, titanium oxide, and tantalum oxide. A hole accumulation layer is formed at an interface on the light-receiving surface side of the semiconductor substrate 11 by an electric field induced by the fixed charge film 45. The hole accumulation layer suppresses generation of electrons from the interface. The color filter 40 is provided on the back surface side of the semiconductor substrate 11. The color filter 40 is, for example, in contact with the fixed charge film 45 and is included at a position facing the sensor pixel 12 via the fixed charge film 45. The light receiving lens 50 is, for example, in contact with the color filter 40 and is included at a position facing the sensor pixel 12 via the color filter 40 and the fixed charge film 45.

The second substrate 20 is formed by stacking an insulating layer 52 on the semiconductor substrate 21. The second substrate 20 includes the insulating layer 52 as a part of the interlayer insulating film 51. The insulating layer 52 is included in a gap between the semiconductor substrate 21 and the semiconductor substrate 31. The semiconductor substrate 21 is formed of a silicon substrate. The second substrate 20 includes one readout circuit 22 for every four sensor pixels 12. The second substrate 20 has a structure in which a readout circuit 22 is included in a portion on the front surface side (third substrate 30 side) of the semiconductor substrate 21. The second substrate 20 is bonded to the first substrate 10 with the back surface of the semiconductor substrate 11 facing the front surface side of the semiconductor substrate 21. That is, the second substrate 20 is bonded to the first substrate 10 in a face-to-back manner. The second substrate 20 further includes an insulating layer 53 penetrating the semiconductor substrate 21 in the same layer as the semiconductor substrate 21. The second substrate 20 includes the insulating layer 53 as a part of the interlayer insulating film 51. The insulating layer 53 is included in such a manner as to cover a side surface of a through wire 54 to be described later.

The stacked body including the first substrate 10 and the second substrate 20 includes the interlayer insulating film 51 and the through wire 54 included in the interlayer insulating film 51. The stacked body has one through wire 54 for each sensor pixel 12. The through wire 54 extends in the normal direction of the semiconductor substrate 21 and penetrates a portion including the insulating layer 53 in the interlayer insulating film 51. The first substrate 10 and the second substrate 20 are electrically connected to each other by the through wire 54. Specifically, the through wire 54 is electrically connected to the floating diffusion FD and a connection wire 55 to be described later.

The stacked body including the first substrate 10 and the second substrate 20 further includes through wires 47 and 48 included in the interlayer insulating film 51. The stacked body has one through wire 47 and one through wire 48 for each sensor pixel 12. Each of the through wires 47 and 48 extends in the normal direction of the semiconductor substrate 21 and penetrates the portion including the insulating layer 53 in the interlayer insulating film 51. The first substrate 10 and the second substrate 20 are electrically connected to each other by the through wires 47 and 48. Specifically, the through wire 47 is electrically connected to the p-well layer 42 of the semiconductor substrate 11 and a wire in the second substrate 20. The through wire 48 is electrically connected to a transfer gate TG and a pixel drive line 23.

The second substrate 20 includes, for example, in the insulating layer 52, a plurality of connection sections 59 electrically connected to the readout circuits 22 and the semiconductor substrate 21. The second substrate 20 further includes, for example, a wiring layer 56 on the insulating layer 52. The wiring layer 56 includes, for example, an insulating layer 57 and a plurality of pixel drive lines 23 and a plurality of vertical signal lines 24 included in the insulating layer 57. The wiring layer 56 further includes, for example, a plurality of connection wires 55 in the insulating layer 57 with one connection wire provided for every four sensor pixels 12. The connection wire 55 electrically connects through wires 54, electrically connected to floating diffusions FD included in four sensor pixels 12 sharing a readout circuit 22, to each other. Here, the total number of the through wires 54 and 48 is larger than the total number of the sensor pixels 12 included in the first substrate 10 and is twice the total number of the sensor pixels 12 included in the first substrate 10. In addition, the total number of the through wires 54, 48, and 47 is larger than the total number of the sensor pixels 12 included in the first substrate 10 and is three times the total number of the sensor pixels 12 included in the first substrate 10.

The wiring layer 56 further includes, for example, a plurality of pad electrodes 58 in the insulating layer 57. Each of the pad electrodes 58 is formed of metal such as copper (Cu) or aluminum (Al). Each of the pad electrodes 58 is exposed on the front surface of the wiring layer 56. Each of the pad electrodes 58 is used for electrical connection between the second substrate 20 and the third substrate 30 and bonding between the second substrate 20 and the third substrate 30. For example, one pad electrode 58 is provided for each pair of a pixel drive line 23 and a vertical signal line 24. Here, the total number of pad electrodes 58 (or the total number of junctions between the pad electrodes 58 and the pad electrodes 64 (described later) is smaller than the total number of sensor pixels 12 included in the first substrate 10.

The third substrate 30 is formed by stacking an interlayer insulating film 61 on the semiconductor substrate 31, for example. As will be described later, since the third substrate 30 is bonded to the second substrate 20 with the front surfaces thereof facing each other, the description in the vertical direction is opposite to the vertical direction in the drawings when the structure in the third substrate 30 is described. The semiconductor substrate 31 is formed of a silicon substrate. The third substrate 30 has a structure in which a logic circuit 32 is included in a portion on the front surface side of the semiconductor substrate 31. The third substrate 30 further includes, for example, a wiring layer 62 on the interlayer insulating film 61. The wiring layer 62 includes, for example, an insulating layer 63 and a plurality of pad electrodes 64 included in the insulating layer 63. The plurality of pad electrodes 64 is electrically connected to the logic circuit 32. Each of the pad electrodes 64 is formed of, for example, Cu (copper). Each of the pad electrodes 64 is exposed on the front surface of the wiring layer 62. Each of the pad electrodes 64 is used for electrical connection between the second substrate 20 and the third substrate 30 and bonding between the second substrate 20 and the third substrate 30. In addition, the number of pad electrodes 64 is not necessarily plural, and even one pad electrode can implement electric connection with the logic circuit 32. The second substrate 20 and the third substrate 30 are electrically connected to each other by bonding between the pad electrodes 58 and 64. That is, the gate (transfer gate TG) of the transfer transistor TR is electrically connected to the logic circuit 32 via the through wire 54 and the pad electrodes 58 and 64. The third substrate 30 is bonded to the second substrate 20 with the front surface of the semiconductor substrate 31 facing the front surface side of the semiconductor substrate 21. That is, the third substrate 30 is bonded to the second substrate 20 in a face-to-face manner.

The first substrate 10 and the second substrate 20 in FIGS. 30 and 23 correspond to the semiconductor substrate 130 and the semiconductor substrate 230 of the first embodiment, respectively. A semiconductor substrate corresponding to the third substrate 30 described above can also be stacked on the semiconductor substrate 230. Furthermore, four or more semiconductor substrates can be stacked. Such a configuration in which three or more layers of semiconductor substrates are stacked can be applied to each of the embodiments of the present disclosure.

Note that the arrangement of circuit elements constituting a pixel block 100 is not limited to the example of FIG. 5. For example, all the elements of the pixel circuit 120 may be included in the semiconductor substrate 130. A pixel circuit, a signal processing circuit, a memory circuit, a logic circuit, and others formed by an analog circuit or a digital circuit can be desirably disposed in the semiconductor substrate 230 or a semiconductor substrate further added desirably.

### 6. Application Examples

FIG. 32 is a diagram illustrating an example of a schematic configuration of an imaging system 7 including the imaging device 1 according to one of the embodiments and the modifications thereof.

The imaging system 7 is an electronic device such as an imaging device, such as a digital still camera or a video camera, or a portable terminal device such as a smartphone or a tablet terminal. The imaging system 7 includes, for example, the imaging device 1 according to one of the above-described embodiments and the modifications thereof, a DSP circuit 743, a frame memory 744, a display section 745, a storage section 746, an operation section 747, and a power supply section 748. In the imaging system 7, the imaging device according one of the embodiments and the modifications thereof, the DSP circuit 743, the frame memory 744, the display section 745, the storage section 746, the operation section 747, and the power supply section 748 are mutually connected via a bus line 749.

The imaging device 1 according to one of the embodiments and the modifications thereof outputs image data corresponding to incident light. The DSP circuit 743 is a signal processing circuit that processes a signal (image data) output from the imaging device 1 according to one of the embodiments and the modifications thereof. The frame memory 744 temporarily holds image data processed by the DSP circuit 743 for every frame. The display section 745 includes a panel-type display device such as a liquid crystal panel or an organic electro luminescence (EL) panel and displays a moving image or a still image captured by the imaging device 1 according to one of the embodiments and the modifications thereof. The storage section 746 records the image data of a moving image or a still image captured by the imaging device 1 according to one of the embodiments and the modifications thereof in a recording medium such as a semiconductor memory or a hard disk. The operation section 747 issues operation commands for various functions of the imaging system 7 on the basis of an operation by a user. The power supply section 748 supplies various power sources that serve as operation power sources of the imaging device 1 according to one of the embodiments and the modifications thereof, the DSP circuit 743, the frame memory 744, the display section 745, the storage section 746, and the operation section 747 to these supply targets as appropriate.

Next, an imaging procedure in the imaging system 7 will be described.

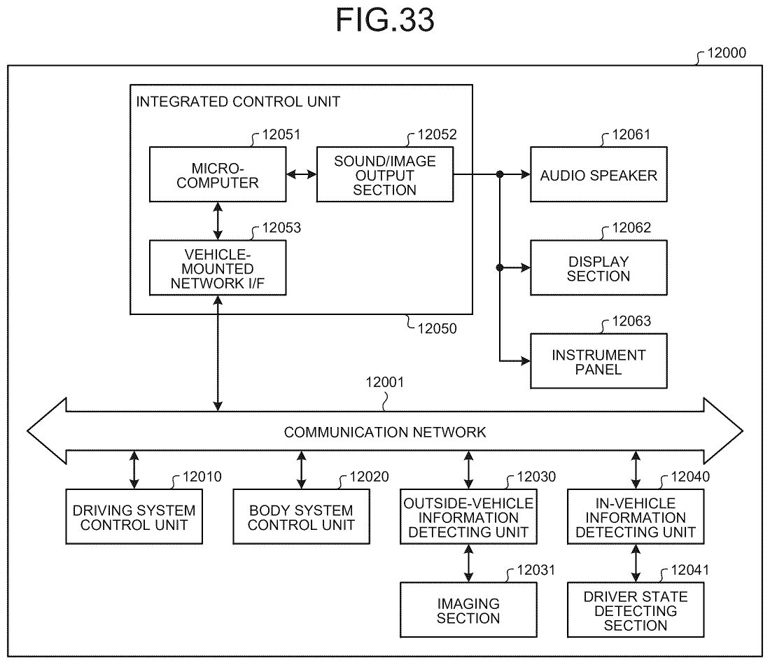

FIG. 33 is a diagram illustrating an example of a flowchart of an imaging operation in the imaging system 7. A user instructs to start imaging by operating the operation section 747 (Step S101). Then, the operation section 747 transmits an imaging command to the imaging device 1 (Step S102). Upon receiving the imaging command, the imaging device 1 (specifically, system control circuit 36) executes imaging by a predetermined imaging scheme (Step S103).

The imaging device 1 outputs image data obtained by the imaging to the DSP circuit 743. Incidentally, the image data refers to data, for all the pixels, of pixel signals generated on the basis of charges temporarily held in floating diffusions FD. The DSP circuit 743 performs predetermined signal processing (for example, noise reduction processing) on the basis of the image data input from the imaging device 1 (Step S104). The DSP circuit 743 causes the frame memory 744 to hold the image data having been subjected to the predetermined signal processing, and the frame memory 744 causes the storage section 746 to record the image data (Step S105). In this manner, imaging in the imaging system 7 is performed.

In the present application example, the imaging device 1 according to one of the above-described embodiments and the modifications thereof is applied to the imaging system 7. As a result, the imaging device 1 can be downsized or have high definition, and thus it is possible to provide the imaging system 7 that is downsized or has high definition.

### 7. Application Example to Mobile Body

The technology according to the present disclosure (present technology) can be applied to various products. For example, the technology according to the present disclosure may be implemented as a device to be mounted on a mobile body of any type such as automobiles, electric vehicles, hybrid electric vehicles, motorcycles, bicycles, personal mobilities, airplanes, drones, ships, and robots.

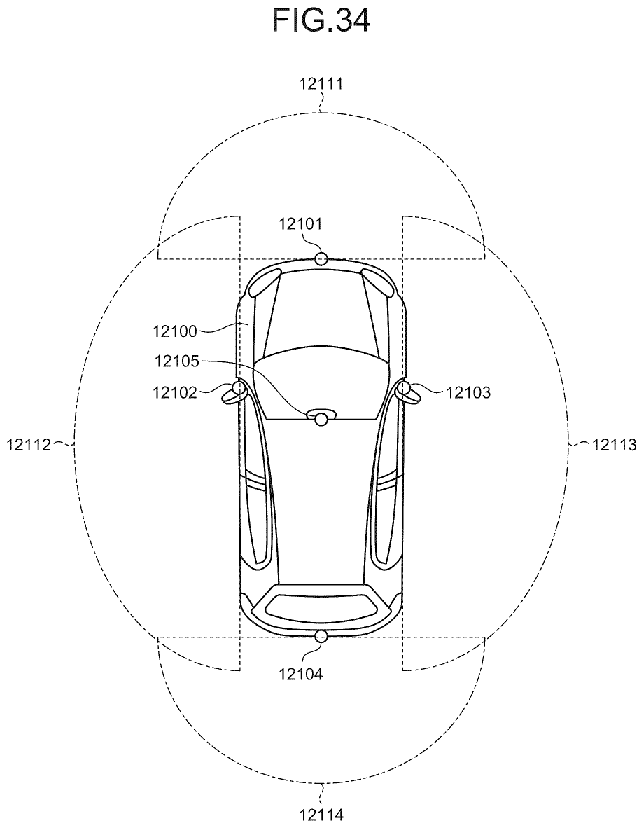

FIG. 34 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 34, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 34, an audio speaker 12061, a display section 12062, and an instrument panel 12063 are illustrated as the output device. The display section 12062 may, for example, include at least one of an on-board display and a head-up display.

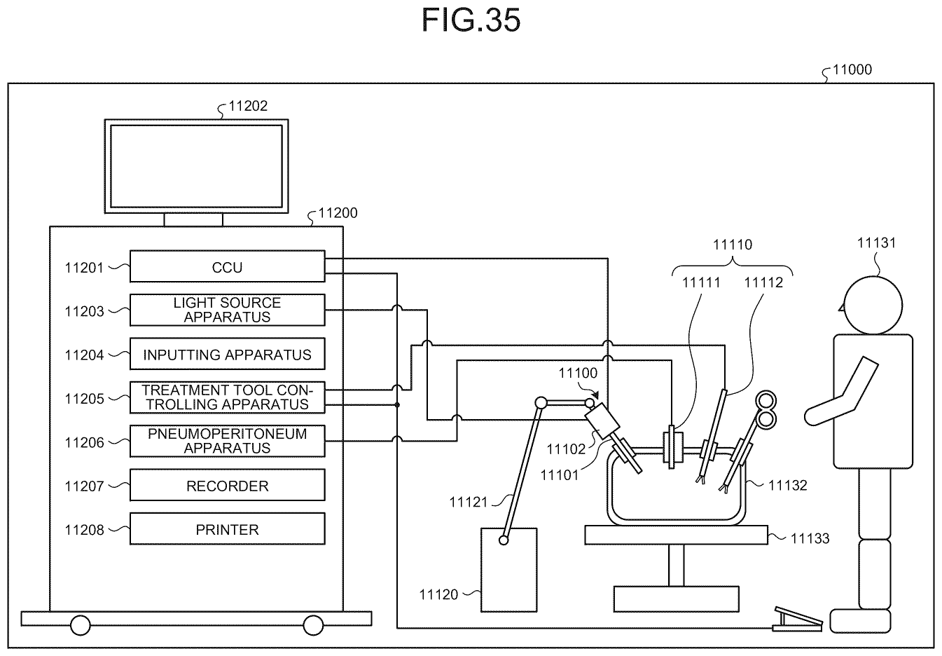

FIG. 35 is a diagram depicting an example of the installation position of the imaging section 12031.

In FIG. 35, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 35 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the vehicle control system to which the technology according to the present disclosure can be applied has been described above. The technology according to the present disclosure can be applied to the imaging section 12031 in the above-described configuration. Specifically, the imaging element 1 in FIG. 1 can be applied to the imaging section 12031. By applying the technology according to the present disclosure to the imaging section 12031, it is possible to prevent deterioration of the image quality of the imaging section 12031.

### 8. Application Example to Endoscopic Surgery System

The technology according to the present disclosure (present technology) can be applied to various products. For example, the technology according to the present disclosure may be applied to an endoscopic surgery system.

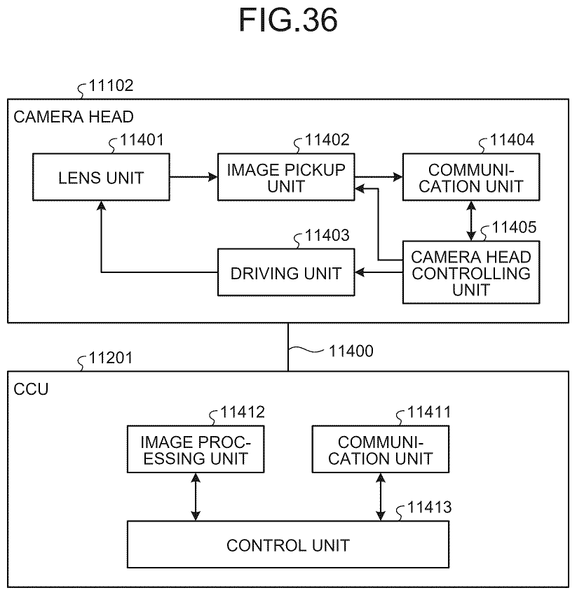

FIG. 36 is a view depicting an example of a schematic configuration of an endoscopic surgery system to which the technology according to an embodiment of the present disclosure (present technology) can be applied.

In FIG. 36, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy treatment tool 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body lumen of the patient 11132, and a camera head 11102 connected to a proximal end of the lens barrel 11101. In the example depicted, the endoscope 11100 is depicted which includes as a hard mirror having the lens barrel 11101 of the hard type. However, the endoscope 11100 may otherwise be included as a soft mirror having the lens barrel 11101 of the soft type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body lumen of the patient 11132 through the objective lens. It is to be noted that the endoscope 11100 may be a direct view mirror or may be a perspective view mirror or a side view mirror.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy treatment tool 11112 for cautery or incision of a tissue, sealing of a blood vessel or the like. A pneumoperitoneum apparatus 11206 feeds gas into a body lumen of the patient 11132 through the pneumoperitoneum tube 11111 to inflate the body lumen in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

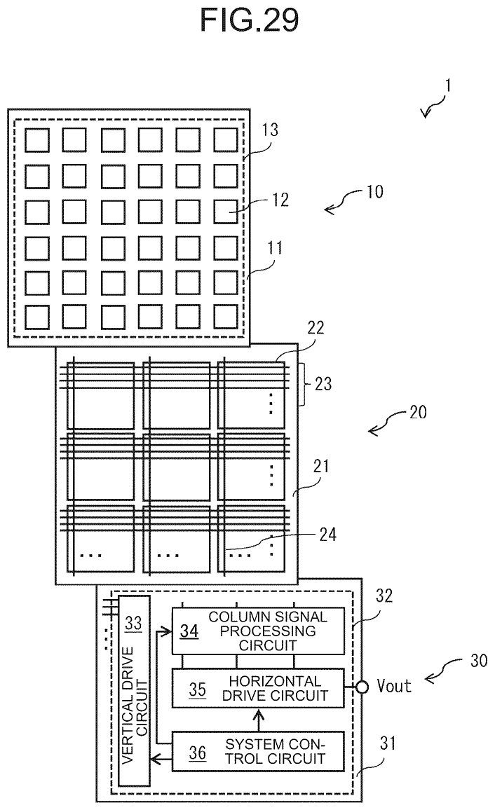

FIG. 29 is a block diagram depicting an example of a functional configuration of the camera head 11102 and the CCU 11201 depicted in FIG. 36.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy treatment tool 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

An example of an endoscopic surgery system to which the technology according to the present disclosure can be applied has been described above. The technology according to the present disclosure can be applied to the endoscope 11100 or the image pickup unit 11402 of the camera head 11102 among the above-described components. Specifically, the imaging element 1 in FIG. 1 can be applied to the image pickup unit 11402. By applying the technology according to the present disclosure to the image pickup unit 11402, it is possible to prevent deterioration of the image quality of the image pickup unit 11402.

Note that, in this example, the endoscopic surgery system has been described as an example, however, the technology according to the present disclosure may be applied to other systems such as a microscopic surgery system.

Although the embodiments of the present disclosure have been described above, the technical scope of the present disclosure is not limited to the above embodiments as they are, and various modifications can be made without departing from the gist of the present disclosure. In addition, components of different embodiments and modifications may be combined as appropriate.

Note that the effects described herein are merely examples and are not limited, and other effects may also be achieved.

Note that the present technology can also have the following configurations.
(1) An imaging element comprising:

a pixel including: a photoelectric conversion section that performs photoelectric conversion of incident light, the photoelectric conversion section formed in a semiconductor substrate; a charge holding section that holds a charge generated by the photoelectric conversion; and a charge transfer section that transfers the charge to the charge holding section;

a well region electrode disposed by being embedded in the semiconductor substrate, the well region electrode connected to a well region of the semiconductor substrate; and

a signal generation section that generates a pixel signal, the pixel signal corresponding to the charge held in the charge holding section.
(2) The imaging element according to the above (1), wherein the charge holding section is disposed on a front surface of the semiconductor substrate.
(3) The imaging element according to the above (2), wherein the well region electrode is disposed under the charge holding section in the semiconductor substrate.
(4) The imaging element according to any one of the above (1) to (3), wherein the well region electrode is made of polycrystalline silicon containing an impurity.
(5) The imaging element according to any one of the above (1) to (4), further comprising a semiconductor region disposed in a region adjacent to the well region electrode of the semiconductor substrate, the semiconductor region having an impurity concentration higher than an impurity concentration of the well region.
(6) The imaging element according to any one of the above (1) to (5),

wherein the semiconductor substrate includes a wiring region disposed adjacent to a surface, and

the charge transfer section is disposed under a surface where the semiconductor substrate is in contact with the wiring region.
(7) The imaging element according to the above (6), wherein the charge transfer section transfers the charge of the photoelectric conversion section in a thickness direction of the semiconductor substrate.
(8) The imaging element according to the above (6), wherein the charge transfer section is disposed on the well region electrode in the semiconductor substrate.
(9) The imaging element according to the above (8), wherein the charge transfer section includes a gate electrode made of polycrystalline silicon containing an impurity.
(10) The imaging element according to any one of the above (1) to (9), further comprising an isolation section disposed at a boundary of the pixel.
(11) The imaging element according to the above (10), wherein the well region electrode is disposed in the isolation section.
(12) The imaging element according to the above (10), wherein the charge transfer section is disposed adjacent to the isolation section.
(13) The imaging element according to the above (10), wherein the charge transfer section includes a gate electrode connected to a columnar wire disposed in the isolation section.
(14) The imaging element according to the above (13),

wherein the semiconductor substrate includes a wiring region disposed adjacent to a surface, and

the columnar wire is connected with the gate electrode under a surface where the semiconductor substrate is in contact with the wiring region.
(15) The imaging element according to the above (10), wherein the isolation section has a shape penetrating the semiconductor substrate.
(16) The imaging element according to the above (15), further comprising an isolation section electrode disposed in the isolation section under the well region electrode of the semiconductor substrate.
(17) The imaging element according to the above (16), wherein the isolation section electrode is applied with a bias voltage.
(18) An electronic device comprising:

a pixel including: a photoelectric conversion section that performs photoelectric conversion of incident light, the photoelectric conversion section formed in a semiconductor substrate; a charge holding section that holds a charge generated by the photoelectric conversion; and a charge transfer section that transfers the charge to the charge holding section;

a well region electrode disposed by being embedded in the semiconductor substrate, the well region electrode connected to a well region of the semiconductor substrate;

a signal generation section that generates a pixel signal, the pixel signal corresponding to the charge held in the charge holding section; and

a processing circuit that processes the pixel signal.

### REFERENCE SIGNS LIST

1 IMAGING ELEMENT
90 PIXEL ARRAY SECTION
94 COLUMN SIGNAL PROCESSING SECTION
100 PIXEL BLOCK
101, 101a, 101b, 101c, 101d PHOTOELECTRIC CONVERSION SECTION
102, 102a, 102b, 102c, 102d CHARGE TRANSFER SECTION
103, 103a, 103b, 103c, 103d CHARGE HOLDING SECTION
110, 110a, 110b, 110c, 110d, 110e, 110f, 110g, 110h PIXEL
129 SIGNAL GENERATION SECTION
130, 230 SEMICONDUCTOR SUBSTRATE
131 to 133, 137, 139 SEMICONDUCTOR REGION
142, 144 ISOLATION SECTION
143 WELL REGION ELECTRODE
148 INSULATING LAYER
150, 155 GATE ELECTRODE
153 CHARGE HOLDING SECTION COMMON ELECTRODE
160, 260 WIRING REGION
269 THROUGH WIRE

What is claimed is:

1. An imaging element, comprising:
a pixel including: a photoelectric conversion section that performs photoelectric conversion of incident light, the photoelectric conversion section formed in a semiconductor substrate; a charge holding section that holds a charge generated by the photoelectric conversion; and a charge transfer section that transfers the charge to the charge holding section;
a well region electrode disposed by being embedded in the semiconductor substrate, the well region electrode connected to a well region of the semiconductor substrate; and
a signal generation section that generates a pixel signal, the pixel signal corresponding to the charge held in the charge holding section.

2. The imaging element according to claim 1, wherein the charge holding section is disposed on a front surface of the semiconductor substrate.

3. The imaging element according to claim 2, wherein the well region electrode is disposed under the charge holding section in the semiconductor substrate.

4. The imaging element according to claim 1, wherein the well region electrode is made of polycrystalline silicon containing an impurity.

5. The imaging element according to claim 1, further comprising a semiconductor region disposed in a region adjacent to the well region electrode of the semiconductor substrate, the semiconductor region having an impurity concentration higher than an impurity concentration of the well region.

6. The imaging element according to claim 1,
wherein the semiconductor substrate includes a wiring region disposed adjacent to a surface, and
the charge transfer section is disposed under a surface where the semiconductor substrate is in contact with the wiring region.

7. The imaging element according to claim 6, wherein the charge transfer section transfers the charge of the photoelectric conversion section in a thickness direction of the semiconductor substrate.

8. The imaging element according to claim 6, wherein the charge transfer section is disposed on the well region electrode in the semiconductor substrate.

9. The imaging element according to claim 8, wherein the charge transfer section includes a gate electrode made of polycrystalline silicon containing an impurity.

10. The imaging element according to claim 1, further comprising an isolation section disposed at a boundary of the pixel.

11. The imaging element according to claim 10, wherein the well region electrode is disposed in the isolation section.

12. The imaging element according to claim 10, wherein the charge transfer section is disposed adjacent to the isolation section.

13. The imaging element according to claim 10, wherein the charge transfer section includes a gate electrode connected to a columnar wire disposed in the isolation section.

14. The imaging element according to claim 13,
wherein the semiconductor substrate includes a wiring region disposed adjacent to a surface, and
the columnar wire is connected with the gate electrode under a surface where the semiconductor substrate is in contact with the wiring region.

15. The imaging element according to claim 10, wherein the isolation section has a shape penetrating the semiconductor substrate.

16. The imaging element according to claim 15, further comprising an isolation section electrode disposed in the isolation section under the well region electrode of the semiconductor substrate.

17. The imaging element according to claim 16, wherein the isolation section electrode is applied with a bias voltage.

18. An electronic device, comprising:
a pixel including: a photoelectric conversion section that performs photoelectric conversion of incident light, the photoelectric conversion section formed in a semiconductor substrate; a charge holding section that holds a charge generated by the photoelectric conversion; and a charge transfer section that transfers the charge to the charge holding section;
a well region electrode disposed by being embedded in the semiconductor substrate, the well region electrode connected to a well region of the semiconductor substrate;
a signal generation section that generates a pixel signal, the pixel signal corresponding to the charge held in the charge holding section; and
a processing circuit that processes the pixel signal.
